(19) United States
(12) Patent Application Publication
(10) Pub. No.: US 2025/0300088 A1
(43) Pub. Date: Sep. 25, 2025

(54) INTEGRATED CIRCUIT PACKAGES INCLUDING INTERPOSERS HAVING A GLASS LAYER AND EMBEDDED DIES

(71) Applicant: Intel Corporation, Santa Clara, CA (US)

(72) Inventors: Jeremy Ecton, Gilbert, AZ (US); Srinivas Venkata Ramanuja Pietambaram, Chandler, AZ (US); Gang Duan, Chandler, AZ (US); Brandon C. Marin, Gilbert, AZ (US); Bohan Shan, Chandler, AZ (US)

(73) Assignee: Intel Corporation, Santa Clara, CA (US)

(21) Appl. No.: 18/615,119

(22) Filed: Mar. 25, 2024

(51) Int. Cl. H01L 23/538; H01L 21/48; H01L 21/56; H01L 23/00; H01L 23/48; H01L 25/00; H01L 25/065; H01L 25/10

(52) U.S. Cl. CPC H01L 23/5389; H01L 21/4857; H01L 21/563; H01L 23/5384; H01L 24/16; H01L 24/32; H01L 24/73; H01L 25/0652; H01L 25/105; H01L 25/50; H01L 23/481; H01L 2224/16145; H01L 2224/16227; H01L 2224/32225; H01L 2224/73204

(57) ABSTRACT

Disclosed herein are microelectronic assemblies and related devices and methods. In some embodiments, a microelectronic assembly may include a first layer with an insulating material and a die surrounded by the insulating material; a second layer on the first layer, the second layer including a dielectric material and a conductive pathway through the dielectric material, wherein the conductive pathway includes a conductive trace and a conductive via having an inverted trapezoidal shape; and a third layer on the second layer, the third layer including a glass layer and a conductive through-glass via (TGV), wherein the conductive TGV is electrically coupled to the conductive pathway and the die is electrically coupled to the conductive TGV by the conductive pathway.

### BACKGROUND

Electronic circuits when fabricated on a wafer of semiconductor material, such as silicon, are commonly called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system. Some ICs have specific functionalities, such as memory or processing. Some other ICs have multiple functionalities, such as a system-on-chip (SOC), in which all or most components of a computer or other electronic system are integrated into a single monolithic die.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A and 1B are schematic cross-sectional views of example microelectronic assemblies according to some embodiments of the present disclosure.

FIG. 2 is a schematic cross-sectional view of another example microelectronic assembly according to some embodiments of the present disclosure.

FIG. 3 is a schematic cross-sectional view of yet another example microelectronic assembly according to some embodiments of the present disclosure.

FIG. 4 is a schematic cross-sectional view of yet another example microelectronic assembly according to some embodiments of the present disclosure.

FIGS. 5A-5G are simplified cross-sectional views illustrating various manufacturing steps of the example microelectronic assembly of FIG. 1A according to some embodiments of the present disclosure.

FIGS. 6A-6C are simplified cross-sectional views illustrating various manufacturing steps of the example microelectronic assembly of FIG. 1B according to some embodiments of the present disclosure.

FIGS. 7A-7D are simplified cross-sectional views illustrating various manufacturing steps of the example microelectronic assembly of FIG. 2 according to some embodiments of the present disclosure.

FIGS. 8A-8D are simplified cross-sectional views illustrating various manufacturing steps of the example microelectronic assembly of FIG. 3 according to some embodiments of the present disclosure.

FIGS. 9A-9E are simplified cross-sectional views illustrating various manufacturing steps of the example microelectronic assembly of FIG. 4 according to some embodiments of the present disclosure.

FIG. 10 is a cross-sectional view of a device package that may include one or more microelectronic assemblies in accordance with any of the embodiments disclosed herein.

FIG. 11 is a cross-sectional side view of a device assembly that may include one or more microelectronic assemblies in accordance with any of the embodiments disclosed herein.

FIG. 12 is a block diagram of an example computing device that may include one or more microelectronic assemblies in accordance with any of the embodiments disclosed herein.

### DETAILED DESCRIPTION

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in a way that limits the broad scope of the present disclosure and its potential applications.

Die partitioning, in which multiple smaller dies are coupled together by high-density interconnects, may achieve smaller form factors and higher yields than utilizing a single, monolithic die. Increasing functionalities required of semiconductor dies in multichip packages and the concomitant need for fine die-to-die interconnections in the face of high cost and low manufacturing device yield due to transistor shrinkage are driving novel packaging approaches such as hyper-chip stacking (with silicon interposer), silicon bridges (e.g., Embedded Multi-die Interconnect Bridge (EMIB)) and 2.5D/3D heterogeneous integration. Heterogeneous integration uses a packaging technology in which dissimilar chips with different functions are integrated within the package using lateral connections, as in 2.5-D packaging architecture, or through-connections, as in 3-D packaging architecture. Although the designs are quite different between 2.5D and 3D packaging architecture, they are both intended to improve package performance by primarily focusing in two directions: (1) reduced package x, y dimensions (e.g., form factor), for example, with chip stacking using thinned chips, and (2) increasing input/output (I/O) density for multichip integration. However, coupling dies together at the fine pitch needed to achieve desired interconnect density has been limited by conventional approaches.

One approach to achieving a finer pitch includes incorporating a glass layer. The structures and assemblies disclosed herein may include a glass layer, also referred to herein as a “glass core,” with vias extending through the glass core for front-to-back connections. A glass core as compared to a conventional epoxy core offers several advantages including higher through-glass via (TGV) density, lower signal losses, and lower total thickness variation (TTV), among others. A glass core may be retained within the substrate (e.g., permanently) or may be included temporarily (e.g., as a removable carrier). The low TTV of less than or equal to 10 microns associated with glass enables meeting stringent via-to-pad overlay requirements, for example, an average of +4-sigma of less than or equal to 4 microns for fine pitch scaling up to 2/2 microns (i.e., 2 microns line width with 2 microns line spacing). A TTV of such glass cores may be around 2 microns to 3 microns, thereby enabling suitable 2.5D and 3D packaging architecture. Glass processing techniques that are known in the art, including laser patterning, may be used to achieve desired results.

A glass layer may be retained within the substrate and may include a cavity structure (e.g., blind cavity and through-cavity) for seating an EMIB. Incorporating through-substrate-vias (TSVs) into an EMIB (also referred to as an “EMIB-T”) enables power to be routed from the bottom of the cavity through the EMIB, which reduces the required number of routing layers through the substrate and typically improves yields. However, assembling EMIBs into multi-die IC packages remains challenging due to the desire for decreased package dimensions and increased I/O density. Further, high cost components (e.g., EMIBs) are scrapped if any portion of the substrate is non-functional (e.g., such as low cost, high risk routing layers). Disclosed herein are embodiments where high cost EMIBs and IC die are incorporated last, after the redistribution layer (RDL) formation, or disaggregated from the package substrate by being incorporated into an interposer that electrically couples to a package substrate. Various ones of the embodiments disclosed herein may help reduce the cost and complexity of assembling multi-die IC packages relative to conventional approaches and increase reliability and functionality of these IC packages during use.

Accordingly, disclosed herein are microelectronic assemblies including a first layer with an insulating material and a die surrounded by the insulating material; a second layer on the first layer, the second layer including a dielectric material and a conductive pathway through the dielectric material, wherein the conductive pathway includes a conductive trace and a conductive via having an inverted trapezoidal shape; and a third layer on the second layer, the third layer including a glass layer and a conductive through-glass via (TGV), wherein the conductive TGV is electrically coupled to the conductive pathway and the die is electrically coupled to the conductive TGV by the conductive pathway.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are stated in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may include substantially monocrystalline semiconductors, such as silicon or germanium, as a base material on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may include alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may include compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may include an intrinsic IV or III-V semiconductor material or alloy, not intentionally doped with any electrically active impurity; in alternate embodiments, nominal impurity dopant levels may be present. In still other embodiments, dies may include a non-crystalline material, such as polymers; for example, the base material may include silica-filled epoxy. In other embodiments, the base material may include high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of input/output (I/O) functions, arithmetic operations, pipelining of data, etc.).

In another example, the terms “package” and “IC package” are synonymous, as are the terms “die” and “IC die.” Note that the terms “chip,” “chiplet,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may include a semiconductor material, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may include a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., metal oxide semiconductor (MOS) FETs (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are included in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO2), borosilicate (e.g., 70-80 wt % SiO2, 7-13 wt % of B2O3, 4-8 wt % Na2O or K2O, and 2-8 wt % of Al2O3) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material includes interlayer low-k dielectric that is provided within the IC die. Within package substrates, and printed circuit boards (PCBs) such insulating material includes organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI). Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects. In some embodiments, the pitch of the DTD interconnects may be different from the pitch of the DTPS interconnects, although, in other embodiments, these pitches may be substantially the same.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may include the same or different insulating materials. In some embodiments, the levels of underfill may include thermoset epoxies with silicon oxide particles; in some embodiments, the levels of underfill may include any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

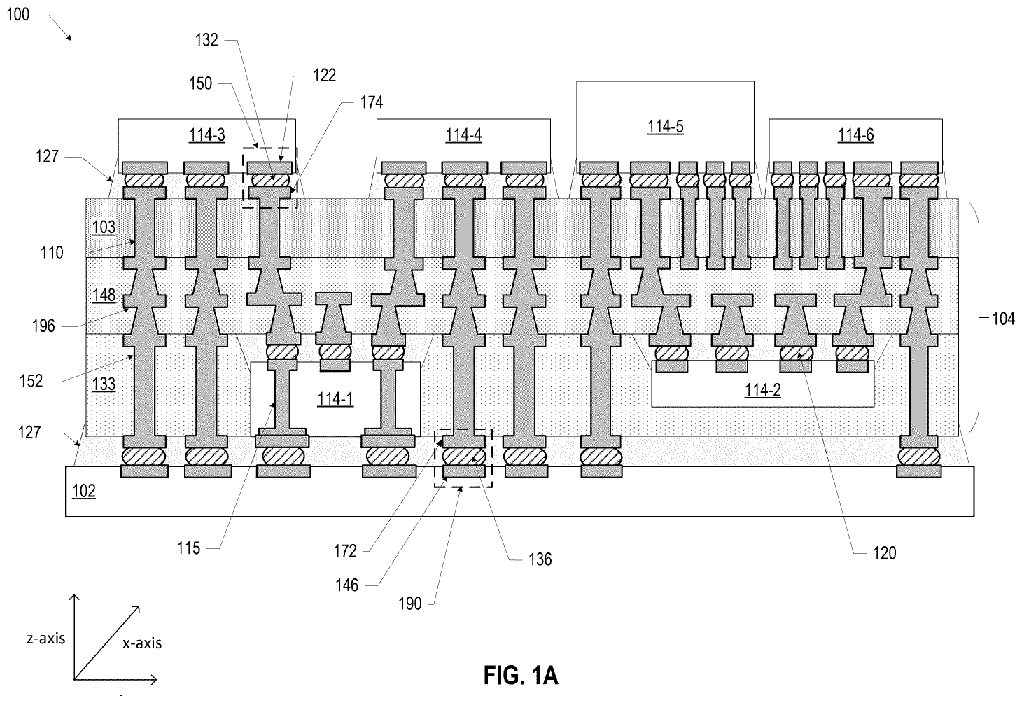

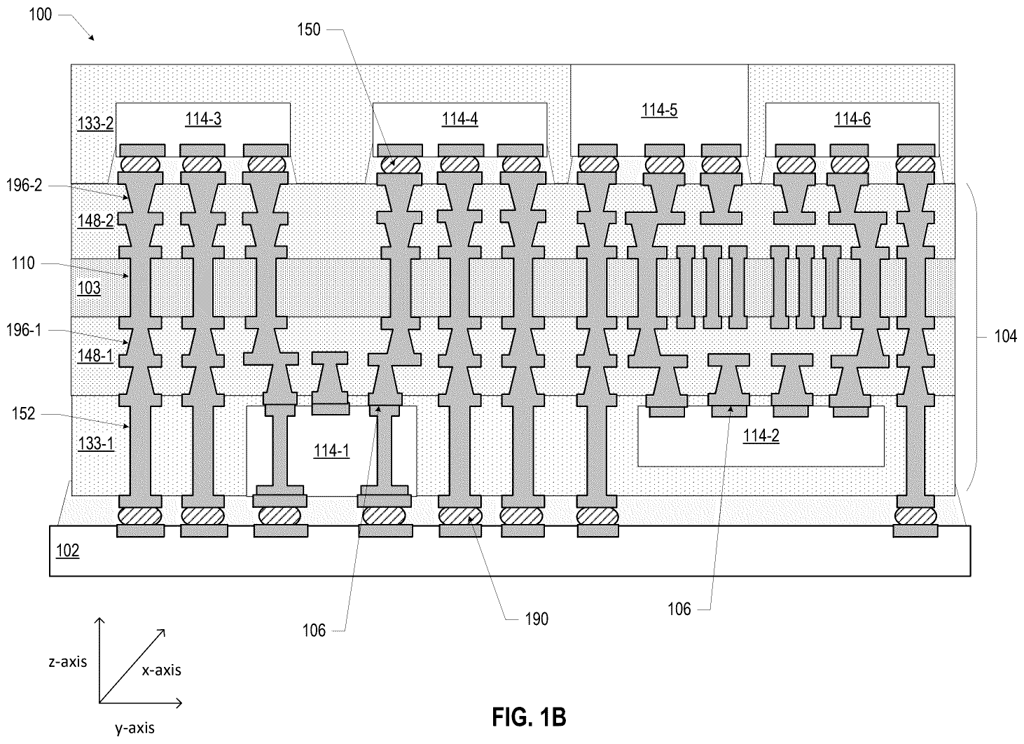

For convenience, if a collection of drawings designated with different letters are present (e.g., FIGS. 1A and 1B), such a collection may be referred to herein without the letters (e.g., as “FIG. 1”). Similarly, if a collection of reference numerals designated with different numbers and/or letters are present (e.g., 148-1, 148-2), such a collection may be referred to herein without the numbers (e.g., as “148”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

FIG. 1A is a schematic cross-sectional view of an example microelectronic assembly 100 according to some embodiments of the present disclosure. An example microelectronic assembly 100 may include an interposer 104, also referred to herein as “a substrate,” having multiple layers and embedded dies 114-1, 114-2. In particular, an interposer 104 may include dies 114-1, 114-2 surrounded by an insulating material 133 in a first layer, a redistribution layer (RDL) 148 with conductive pathways 196 through a dielectric material in a second layer on the first layer, and a core 103 and through-glass vias (TGVs) 110 in a third layer on the second layer. The microelectronic assembly 100 may also include top dies 114-3, 114-4, 114-5, 114-6 electrically coupled to dies 114-1, 114-2 by interconnects 150, by TGVs 110 through the core 103, by conductive pathways 196 through RDL 148, and by interconnects 120.

A material of the core 103 may include glass, such as bulk transparent glass, and also may be referred to herein as “a glass layer.” As used herein, the term “core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the core 103 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the core 103 may be an amorphous solid glass layer. In some embodiments, the core 103 may include silicon and oxygen, as well as any one or more of aluminum, boron, magnesium, calcium, barium, tin, sodium, potassium, strontium, phosphorus, zirconium, lithium, titanium, and zinc. In some embodiments, the core 103 may include a material, e.g., any of the materials described above, with a weight percentage of silicon being at least about 0.5%, e.g., between about 0.5% and 50%, between about 1% and 48%, or at least about 23%. For example, if the core 103 is fused silica, the weight percentage of silicon may be about 47%. In some embodiments, the core 103 may include at least 23% silicon and/or at least 26% oxygen by weight, and, in some further embodiments, the core 103 may further include at least 5% aluminum by weight. In some embodiments, the core 103 may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the core 103 may be a layer of glass that does not include an organic adhesive or an organic material. The core 103 may be distinguished from, for example, the “prepreg” or “RF4” core of a PCB substrate which typically includes glass fibers embedded in a resinous organic material such as an epoxy. In some embodiments, a cross-section of the core 103 in an x-z plane, a y-z plane, and/or an x-y plane of an example coordinate system, shown in FIG. 1A, may be substantially rectangular. In some embodiments, a thickness 191 of a core 103 may be between 100 microns and 2 millimeters (i.e., between 200 microns and 1 millimeter).

TGVs 110 may have any suitable size and shape. TGVs 110 are shown in FIG. 1A as having straight, parallel edges; however, in various embodiments, TGVs 110 may have a tapered or angled contour (e.g., where the TGV 110 has a narrower diameter towards a middle of the core 103 and thicker diameters towards the top and bottom surfaces of the core 103) depending on the processing conditions for generating TGVs 110. TGVs 110 may be formed using any suitable process, including, for example, laser drilling via openings through the core 103 and depositing a conductive material in the openings. TGVs 110 may be formed of any suitable conductive material, such as copper, silver, nickel, gold, aluminum, or other metals or alloys. In some embodiments, a pitch of the TGVs 110 may be between 10 microns and 200 microns (e.g., between 50 microns and 150 microns). In some embodiments, a diameter (e.g., xy-dimension) of the individual TGVs 110 may be between 5 microns and 200 microns (e.g., between 20 microns and 75 microns).

The microelectronic assembly 100 may further include an RDL 148 at the bottom surface of the core 103. The RDL 148 may include conductive pathways 196 (e.g., including conductive traces and/or conductive vias, as shown) through a dielectric material electrically coupled to TGVs 110 in the core 103. The RDL 148 may be manufactured using any suitable technique, such as a semi-additive process, a subtractive etching technique, or other conventional substrate package techniques. In some embodiments, a dielectric material of the RDL 148 may include a build-up film with or without fillers, an oxide-based material (e.g., silicon dioxide, silicon oxynitride, or spin on oxide), or low-k and ultra low-k dielectric (e.g., carbon-doped dielectrics, fluorine-doped dielectrics, porous dielectrics, and organic polymeric dielectrics). In some embodiments, a dielectric material of the RDL 148 may include a bismaleimide triazine (BT) resin, a polyimide material, an epoxy material (e.g., glass reinforced epoxy matrix material, an epoxy build-up film, or the like), or a mold material. The conductive vias of the RDL 148 may have an inverted trapezoidal shape (e.g., upside down V-shape), where a top portion (e.g., the portion towards the core 103) has a smaller cross-section (e.g., xy-dimension) than a bottom portion (e.g., the portion towards the insulating material 133).

The microelectronic assembly 100 of FIG. 1A may also include an insulating material 133 that encapsulates the die 114-1, 114-2 (e.g., around die 114-1, 114-2) and conductive pillars 152. The insulating material 133 may be at a bottom surface of the RDL 148. The die 114-1 may further include TSVs 115 that may be electrically coupled to a package substrate 102 by interconnects 190. The die 114-1, 114-2 may be electrically coupled to the conductive pathways 196 in RDL 148 by interconnects 120. Interconnects 120 may include any suitable interconnects, including, as shown in FIG. 1A, solder or other forms (e.g., as described below with reference to interconnects 150) or, hybrid bonds, as shown in FIG. 1B (e.g., as described below with reference to interconnects 106). In some embodiments, the insulating material 133 may be a mold material, such as an organic polymer with inorganic silicon oxide or aluminum oxide particles, a resin material, or an epoxy material. In some embodiments, the insulating material may include an underfill material or a build-up film without fillers. In some embodiments (not shown) other components, such as heat sinks may be coupled to microelectronic assembly 100 based on particular needs. The conductive pillars 152 may be formed of any suitable conductive material, such as copper, silver, nickel, gold, aluminum, or other metals or alloys, for example. The conductive pillars 152 may be formed using any suitable process, including, for example, a lithographic process or an additive process, such as cold spray or 3-dimensional printing. In some embodiments, the conductive pillars 152 disclosed herein may have a pitch between 55 microns and 1000 microns. The conductive pillars 152 may have any suitable size and shape. In some embodiments, the conductive pillars 152 may have a circular, rectangular, or other shaped cross-section.

The microelectronic assembly 100 may further include one or more top die 114-3, 114-4, 114-5, 114-6 electrically coupled to a top surface of the core 103 by interconnects 150. In particular, conductive contacts 122 on a bottom surface of die 114-3, 114-4, 114-5, 114-6 may be electrically and mechanically coupled to conductive contacts 174 at a top surface of the core 103 by interconnects 150. Interconnects 150 may enable electrical coupling between die 114-1, die 114-2 and die 114-3, 114-4, 114-5, 114-6 through TGVs 110 and conductive pathways 196 in RDL 148. Interconnects 150 disclosed herein may take any suitable form. In some embodiments, a set of interconnects 150 may include solder 132 (e.g., solder bumps or balls that are subject to a thermal reflow to form the interconnects 150). Interconnects 150 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of interconnects 150 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression. In some embodiments, interconnects 150 disclosed herein may have a pitch between about 18 microns and 75 microns. In some embodiments, interconnects in a microelectronic assembly 100 may be metal-to-metal interconnects (e.g., copper-to-copper interconnects, or plated interconnects). In such embodiments, the conductive contacts on either side of the interconnect may be bonded together (e.g., under elevated pressure and/or temperature) without the use of intervening solder or an anisotropic conductive material.

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked). In various embodiments, die 114 may include, or be a part of, one or more of a central processing unit (CPU), a graphics processing unit (GPU), a memory device (e.g., a high-bandwidth memory device), a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express (PCIe) circuitry, Double Data Rate (DDR) transfer circuitry, or other electronic components known in the art.

The microelectronic assembly 100 of FIG. 1A may also include an underfill material 127. In some embodiments, the underfill material 127 may extend between a top surface of die 114-1, 114-2 and the RDL 148 around the associated interconnects 120, and/or between a top surface of the core 103 and a bottom surface of top die 114-3, 114-4, 114-5, 114-6 around the associated interconnects 150. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering die 114-1, 114-2 to the RDL 148 when forming the interconnects 120 or soldering die 114-3, 114-4, 114-5, 114-6 to the core 103 when forming interconnects 150, and then polymerizes and encapsulates the interconnects 120, 150, respectively. The underfill process may include dispensing underfill material in liquid form, allowing the material to flow and fill the interstitial gaps around interconnects 120, 150, and subjecting the assembly to a curing process, such as baking, to solidify the material. In some embodiments, an underfill material 127 may be omitted. Although FIG. 1A shows separate underfill material 127 portions under die 114-3, 114-4, 114-5, and 114-6, the underfill material 127 may be a single underfill material 127 under die 114-3, 114-4, 114-5, and 114-6. The underfill material 127 may be selected to have a coefficient of thermal expansion (CTE) that may mitigate or minimize the stress between die 114 and the RDL 148, the insulating material 133, and/or the core 103 arising from uneven thermal expansion in the microelectronic assembly 100. In some embodiments, the CTE of the underfill material 127 may have a value that is intermediate to the CTE of the RDL 148 (e.g., the CTE of the dielectric material of the RDL 148), the insulating material 133, and/or the core 103, and a CTE of the insulating material of die 114.

Top dies 114-3, 114-4, 114-5, 114-6 may be electrically coupled to respective die 114-1, 114-2 by TGVs 110 and the conductive pathways 196 in the RDL 148. Top dies 114-3, 114-4, 114-5, 114-6 may be electrically coupled to package substrate 102 by TGVs 110, the conductive pathways 196 in the RDL 148, and the conductive pillars in insulating material 133, which may enable power, ground, and signal connectivity between top dies 114-3, 114-4, 114-5, 114-6 and the package substrate 102.

The microelectronic assembly 100 of FIG. 1A may further include a package substrate 102. The package substrate 102 may be electrically coupled to the interposer 104 by interconnects 190. In particular, conductive contacts 172 on a bottom surface of the interposer 104 may be electrically coupled to conductive contacts 146 on a top surface of package substrate 102 by interconnects 190. Interconnects 190 disclosed herein may take any suitable form, including solder balls, as described above with reference to interconnects 120, 150. As shown in FIG. 1A, in some embodiments, a set of interconnects 190 may include solder 136 (e.g., solder bumps or balls that are subject to a thermal reflow to form the interconnects 190). In some embodiments, the interconnects 190 disclosed herein may have a pitch between about 20 microns and 300 microns. In some embodiments, an underfill material 127 may extend between the interposer 104 and the package substrate 102 around the associated interconnects 190.

The microelectronic assembly 100 of FIG. 1A may further include a circuit board (not shown). The circuit board 131 may be a motherboard, for example, and may have other components attached to it. The circuit board may include conductive pathways and other conductive contacts for routing power, ground, and signals through the circuit board, as known in the art.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

Note that in FIG. 1A and in subsequent figures, the interconnects (e.g., interconnects 120, 150, 190, 106) are shown as aligned at the respective interfaces merely for ease of illustration; in actuality, some or all of them may be misaligned. In addition, there may be other components, such as bond pads, landing pads, metallization, etc. present in the assembly that are not shown in the figures to prevent cluttering. Note that FIG. 1A is intended to show relative arrangements of the components within their assemblies, and that, in general, such assemblies may include other components that are not illustrated (e.g., various interfacial layers or various other components related to optical functionality, electrical connectivity, or thermal mitigation). For example, in some further embodiments, the assembly as shown in FIG. 1 may include more dies along with other electrical components. Additionally, although some components of the assemblies are illustrated in FIG. 1A as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

FIG. 1B is a schematic cross-sectional view of another example microelectronic assembly 100 according to some embodiments of the present disclosure. The configuration of the embodiment shown in the figure is like that of FIG. 1A, except for differences as described further. The configuration of microelectronic assembly 100 as described herein includes a first insulating material 133-1 surrounding die 114-1, 114-2 and a first RDL 148-1 with first conductive pathways 196-1 through a dielectric material, where die 114-1, 114-2 are electrically coupled to first conductive pathways 196-1 in the first RDL 133-1 by interconnects 106. An example of interconnect 106 in some embodiments is a hybrid bond comprising metal-metal bonds and dielectric-dielectric bonds. In a general sense, interconnect 106 may include metal-metal bonds and dielectric-dielectric bonds formed between layers on each side of the interconnects, where the layers include bond pads in a dielectric material. Bond pads also may be referred to herein as conductive contacts or metal contacts. A material of the metal-metal bonds may include copper-copper. Dielectric material in the layers surrounding the bond pads may bond with each other. The dielectric material may include an inorganic dielectric (e.g., silicon and oxygen in the form of silicon oxide) or an organic dielectric (e.g., polyimide). The bonded metal and dielectric materials form interconnect 106, comprising hybrid bonds, providing electrical and mechanical coupling. In various embodiments, interconnects 106 may have a pitch of less than 10 microns between adjacent interconnects. In some embodiments, interconnects 106 may have a pitch between 2 microns and 70 microns (e.g., between 2 microns and 10 microns, between 10 microns and 45 microns, or between 45 micron and 70 microns). The microelectronic assembly 100 of FIG. 1B further includes a second RDL 148-2 with second conductive pathways 196-2 through a dielectric material on a top surface of a core 103 and a second insulating material 133-2 surrounding die 114-3, 114-4, 114-5, 114-6. Top die 114-3, 114-4, 114-5, 114-6 may be electrically coupled to the second conductive pathways 196-2 in the second RDL 148-2 by interconnects 150. The dielectric material in the first RDL 148-1 may be a same dielectric material or may be a different dielectric material than the dielectric material in the second RDL 148-2. The first insulating material 133-1 may be a same material or may be a different material than the second insulating material 133-2.

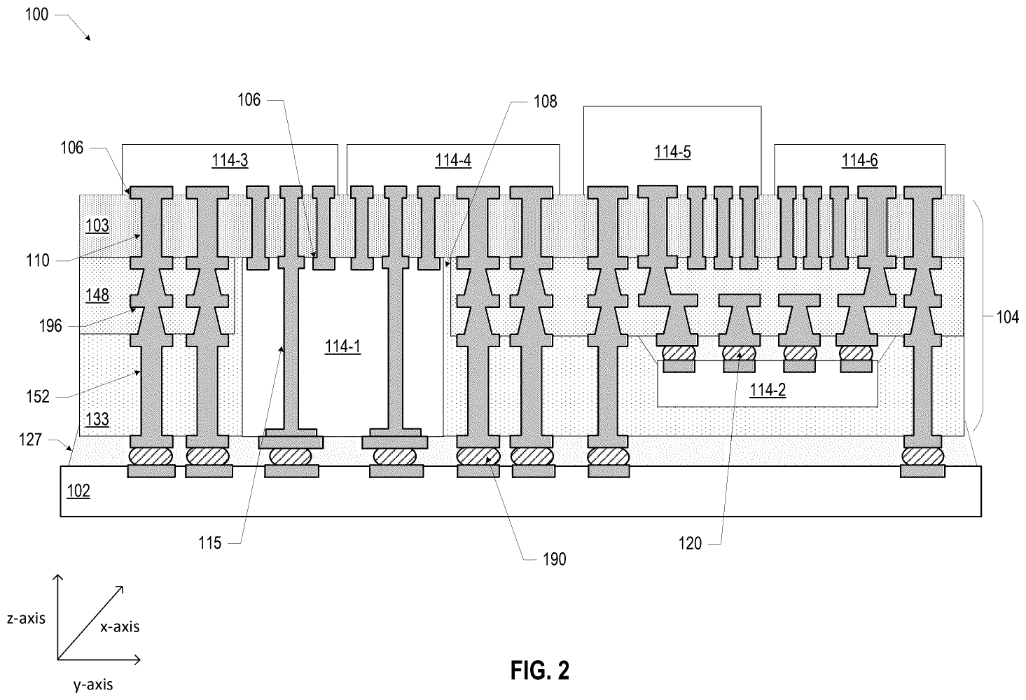

FIG. 2 is a schematic cross-sectional view of another example microelectronic assembly 100 according to some embodiments of the present disclosure. The configuration of the embodiment shown in the figure is like that of FIG. 1A, except for differences as described further. The configuration of microelectronic assembly 100 as described herein further includes a cavity 108 through the RDL 148 and the die 114-1 is within the cavity 108 and electrically coupled to the TGVs 110 in the core 103 by interconnects 106. In some embodiments, the insulating material 133 may fill in and around die 114-1 in the cavity 108. The microelectronic assembly 100 of FIG. 2 further includes top die 114-3, 114-4, 114-5, 114-6 electrically coupled to TGVs 110 in the core 103 by interconnects 106.

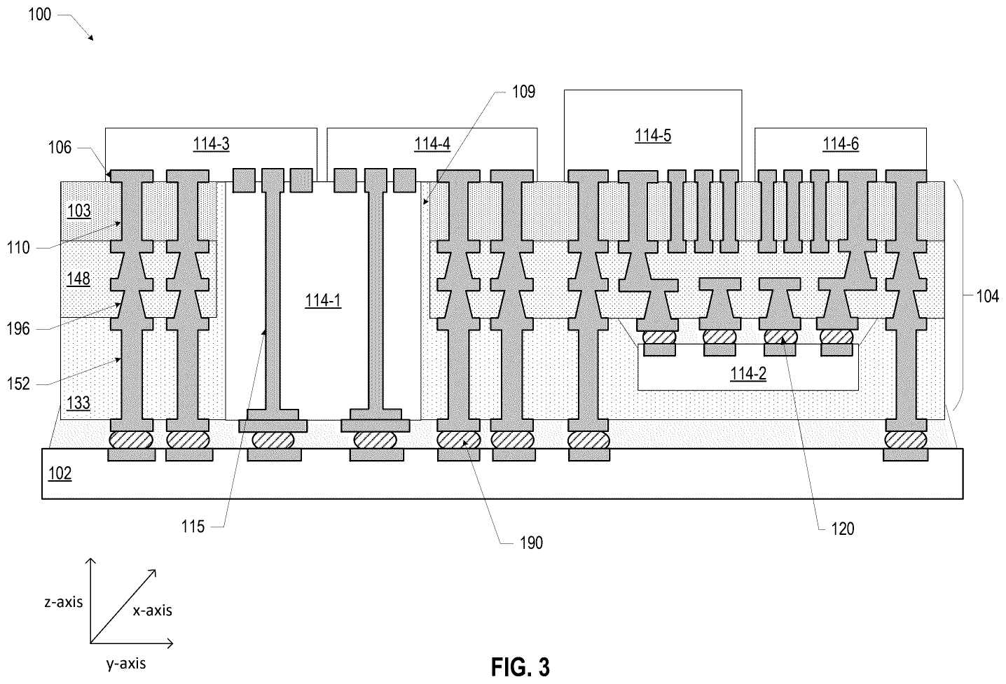

FIG. 3 is a schematic cross-sectional view of another example microelectronic assembly 100 according to some embodiments of the present disclosure. The configuration of the embodiment shown in the figure is like that of FIG. 2, except for differences as described further. The configuration of microelectronic assembly 100 as described herein further includes a cavity 109 through the RDL 148 and through the core 103 and the die 114-1 is within the cavity 109 and electrically coupled to top die 114-3, 114-4 by interconnects 106. Although FIG. 3 illustrates dies 114-1, 114-3, 114-4 electrically coupled by interconnects 106, any suitable interconnects, such as interconnects 150 in FIG. 1, may be used.

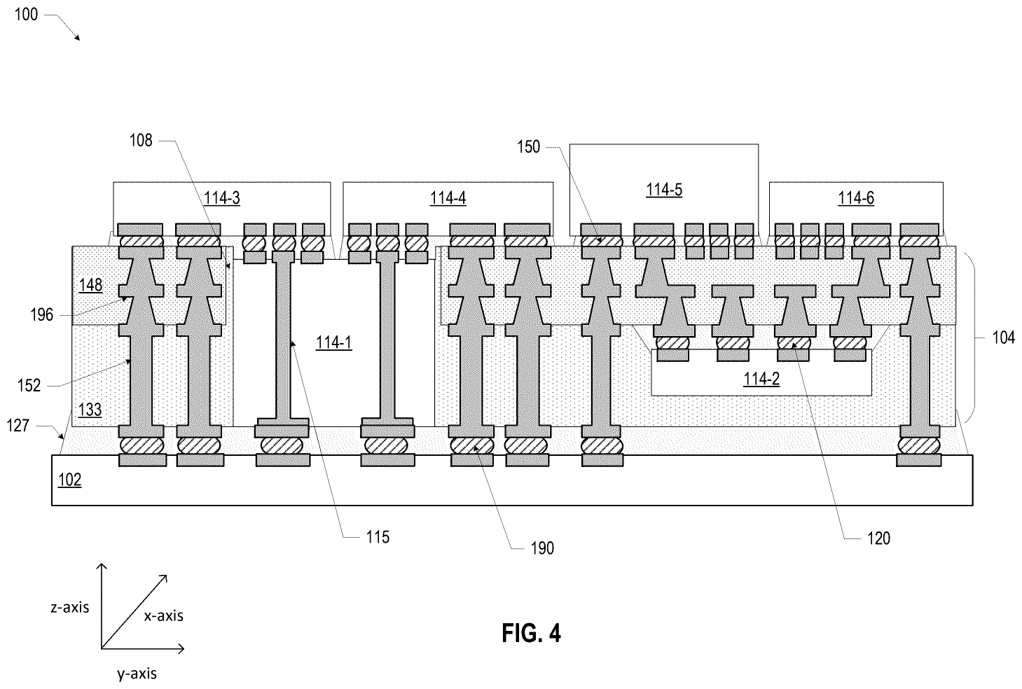

FIG. 4 is a schematic cross-sectional view of another example microelectronic assembly 100 according to some embodiments of the present disclosure. The configuration of the embodiment shown in the figure is like that of FIG. 2, except for differences as described further. The configuration of microelectronic assembly 100 as described herein does not include a core 103. Instead, the microelectronic assembly 100 includes an RDL 148 with a cavity 108, an insulating material 133 surrounding die 114-1, 114-2, where die 114-1 is within the cavity 108 and electrically coupled to top die 114-3, 114-4 by interconnects 150. Although FIG. 4 illustrates dies 114 electrically coupled by interconnects 150, any suitable interconnects, such as interconnects 106 in FIG. 3, may be used.

Although the microelectronic assemblies 100 shown in FIGS. 1-4 have a particular number of die 114 in a particular arrangement, microelectronic assemblies 100 may have any suitable number and arrangement of die 114.

### Example Methods

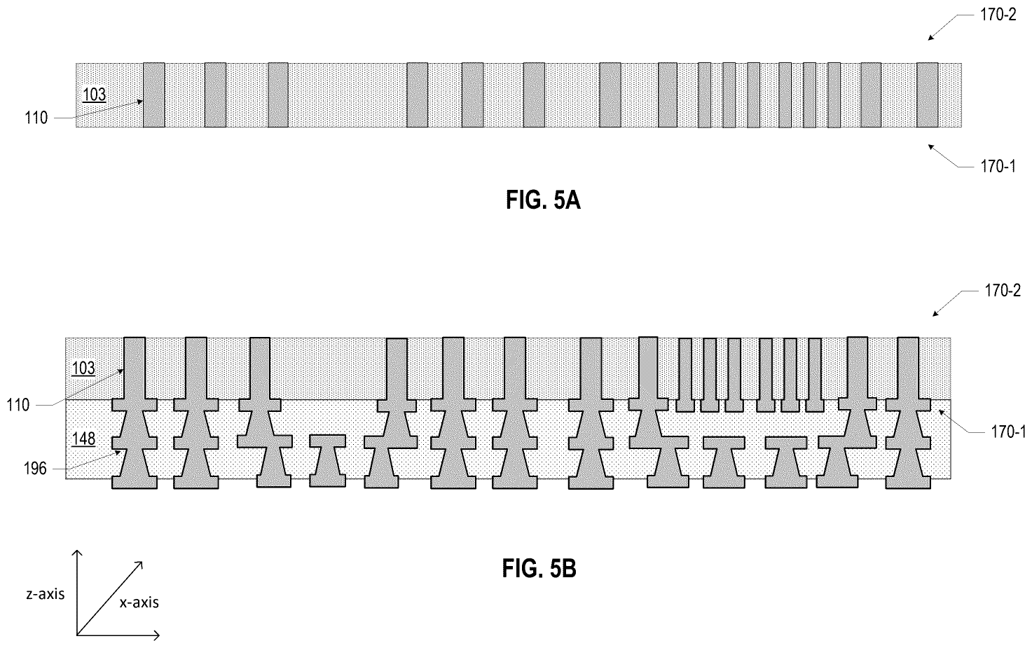

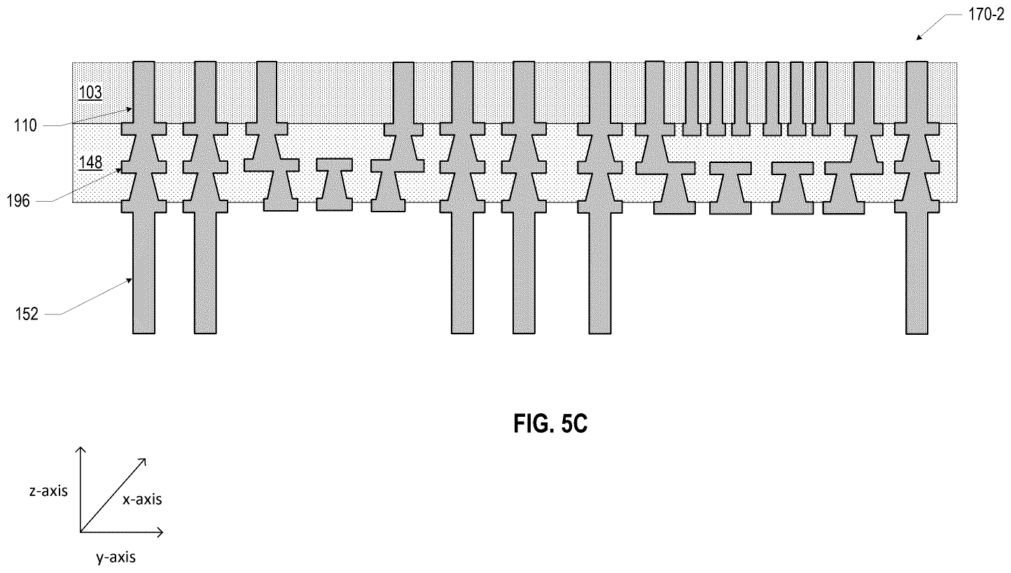

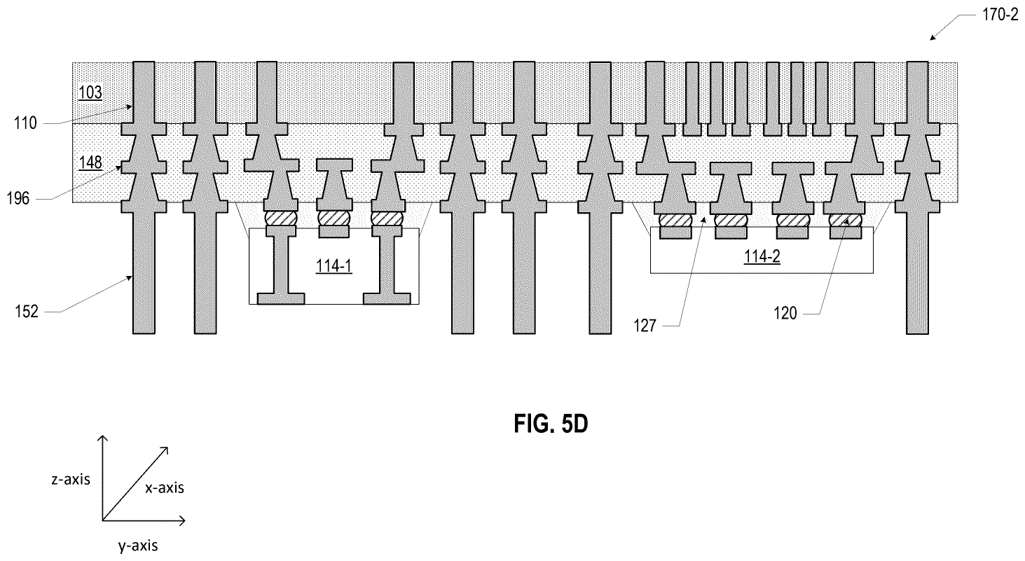

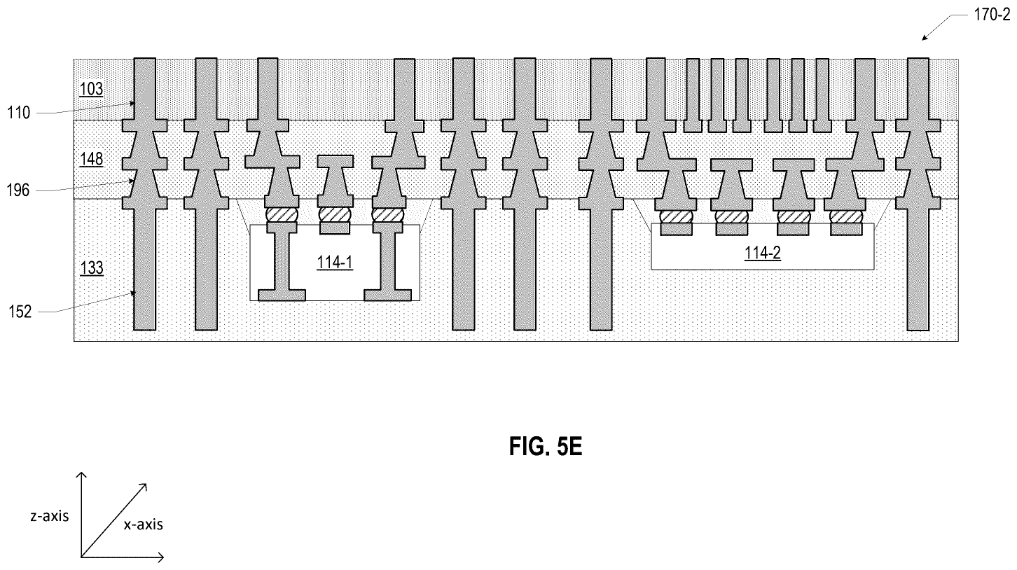

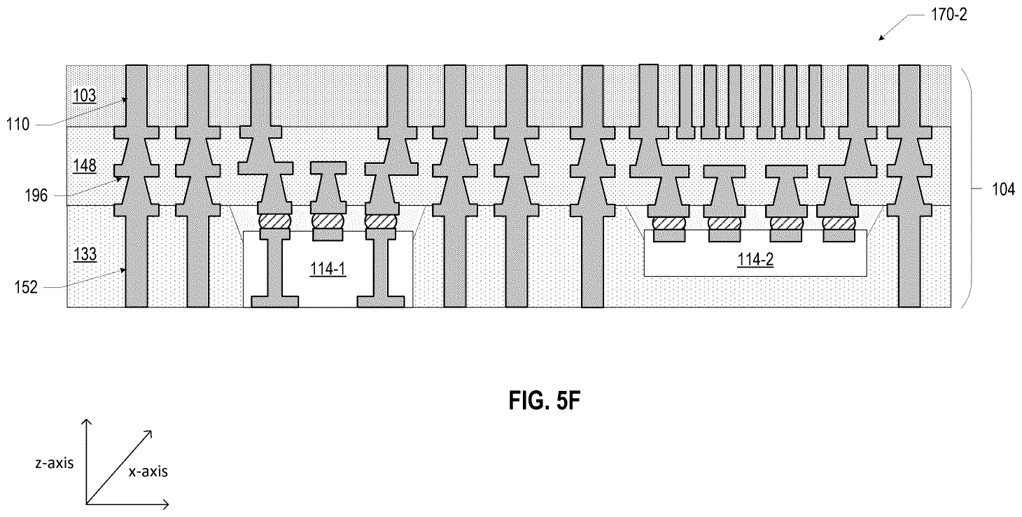

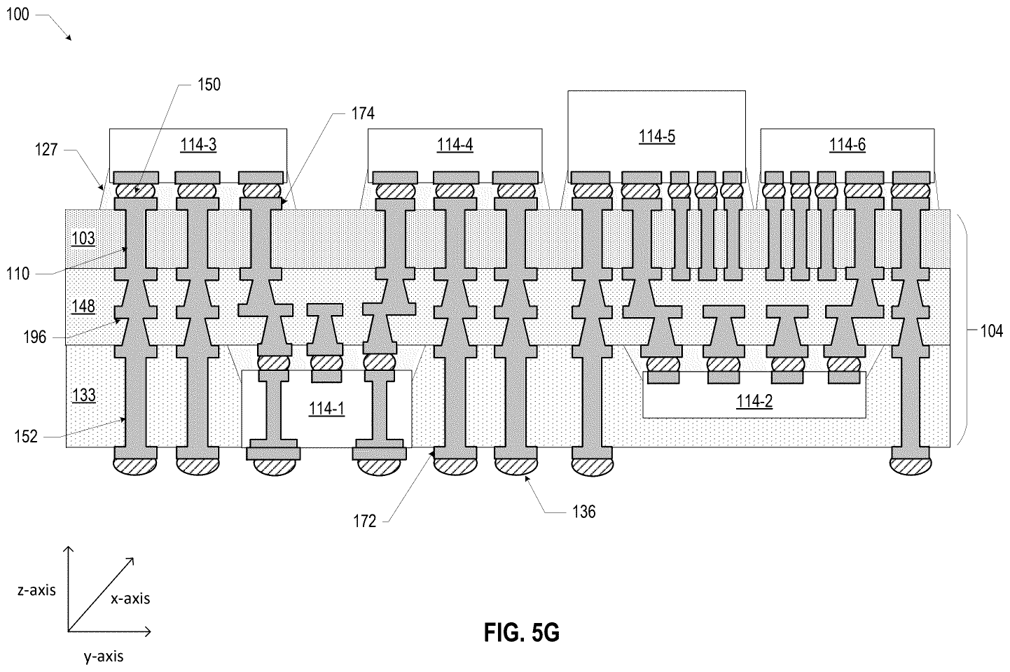

Any suitable techniques may be used to manufacture the microelectronic assemblies 100 disclosed herein. For example, FIGS. 5A-5G are side, cross-sectional views of various stages in an example process for manufacturing the microelectronic assembly 100 of FIG. 1A, in accordance with various embodiments. Although the operations discussed below with reference to FIGS. 5A-5G (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 5A-5G may be modified in accordance with the present disclosure to fabricate others of microelectronic assembly 100 disclosed herein.

FIG. 5A illustrates a core 103 including a first surface 170-1 and a second surface 170-2. The core 103 may include TGVs 110 extending through the core 103. The TGVs 110 may include any suitable conductive material, for example, a metal, such as copper. The assembly of FIG. 5A may be manufactured by forming vias openings in the core 103 and plating copper in the via openings. The via openings may be formed using any suitable process, including lithography, laser assisted wet etch, laser drilling (e.g., laser ablation using excimer laser), or plasma etching. The via openings may have any suitable shape. For example, the via openings may have substantially vertical sidewalls to form rectangular-shaped or cylindrical-shaped vias or may have angled sidewalls to form conical-shaped vias. The shape of the via openings may depend on the process used to form the via openings (e.g., a lithographic process for rectangular-shaped vias and a laser drilling process for conical-shaped vias). In some embodiments, a top surface 170-2 of the core 103 may be attached to a carrier (not shown). The carrier may include any suitable material for providing mechanical stability during manufacturing operations, such as glass.

FIG. 5B illustrates an assembly subsequent to forming an RDL 148 at a first surface 170-1 (e.g., a bottom surface) of the core 103. The RDL 148 may include conductive pathways 196 through a dielectric material. The RDL 148 may be manufactured using any suitable technique, such as a PCB technique, or a redistribution layer technique.

FIG. 5C illustrates an assembly subsequent to forming conductive pillars 152 on a bottom surface of the RDL 148. The conductive pillars 152 may take the form of any of the embodiments disclosed herein, and may be formed using any suitable technique, including a lithographic process or an additive process, such as cold spray or 3-dimensional printing. For example, the conductive pillars 152 may be formed by depositing, exposing, and developing a photoresist layer on the bottom surface of the RDL 148. The photoresist layer may be patterned to form cavities in the shape of the conductive pillars. Conductive material, such as copper, may be deposited in the openings in the patterned photoresist layer to form the conductive pillars 152. The conductive material may be deposited using any suitable process, such as electroplating, sputtering, or electroless plating. The photoresist may be removed to expose the conductive pillars 152. In another example, a photoimageable dielectric may be used to form the conductive pillars 152. The conductive pillars may have any suitable dimensions. For example, in some embodiments, an individual conductive pillar may have an aspect ratio (height:diameter) between 1:1 and 4:1 (e.g., between 1:1 and 3:1). The conductive pillars 152 may have any suitable cross-sectional shape, for example, square, triangular, and oval, among others.

FIG. 5D illustrates an assembly subsequent to placing die 114-1, 114-2, forming interconnects 120, and depositing an underfill material 127 around interconnects 120. Any suitable method may be used to place die 114-1, 114-2, for example, automated pick-and-place. In some embodiments, the interconnects 120 may include solder. In such embodiments, the assembly of FIG. 5D may be subjected to a solder reflow process during which solder components of the interconnects 120 melt and bond to mechanically and electrically couple the die 114-1, 114-2 to the bottom surface of the RDL 148.

FIG. 5E illustrates an assembly subsequent to depositing an insulating material 133 on and around die 114-1, 114-2 and conductive pillars 152. The insulating material 133 may be any suitable material, as described above with reference to FIG. 1A, and may be formed using any suitable process, including lamination, or slit coating and curing.

FIG. 5F illustrates an assembly subsequent to removing a bottom portion of the insulating material 133 and the conductive pillars 152 to expose conductive contacts at the bottom surface of die 114-1. The insulating material 133 and the material of the conductive pillars 152 may be removed using any suitable technique, including grinding, planarization, or etching, such as a wet etch, a dry etch (e.g., a plasma etch), a wet blast, or a laser ablation (e.g., using excimer laser). In some embodiments, the thickness of the insulating material 133 may be minimized to reduce the etching time required.

FIG. 5G illustrates an assembly subsequent to forming conductive contacts 172, 174 on the bottom and top surfaces of the assembly of FIG. 5F, placing die 114-3, 114-4, 114-5, 114-6 on a top surface of the assembly of FIG. 5F, forming interconnects 150, and depositing an underfill material 127 around the interconnects 150. The conductive contacts 172, 174 may be formed using any suitable process, including a semi-additive process. For example, the lithographic process may include applying and patterning a photoresist to top and bottom surfaces of the assembly of FIG. 5F, depositing a conductive material in openings, and removing the photoresist. Conductive material may be deposited using any suitable process, including electrolytic plating. Any suitable method may be used to place die 114-3, 114-4, 114-5, 114-6, for example, automated pick-and-place. In some embodiments, the interconnects 150 may include solder. In such embodiments, the assembly of FIG. 5G may be subjected to a solder reflow process during which solder components of the interconnects 150 melt and bond to mechanically and electrically couple die 114-3, 114-4, 114-5, 114-6 to the top surface of the core 103. In some embodiments, the underfill material 127 around the interconnects 150 may be omitted. Other finishing operations may be performed on the assembly of FIG. 5G, such as depositing solder resist (not shown) and depositing solder 136 on a bottom surface. If multiple assemblies are manufactured together, the assemblies may be singulated. The assembly of FIG. 5G may itself be a microelectronic assembly 100, as shown. Further manufacturing operations may be performed on the microelectronic assembly 100 of FIG. 5G to form other microelectronic assembly 100; for example, the solder 136 may be used to couple the microelectronic assembly 100 of FIG. 5G to a package substrate 102 via interconnects 190, similar to the microelectronic assembly 100 of FIG. 1A, and/or an insulating material 133 (e.g., the second insulating material 133-2 in FIG. 1B) may be deposited on and around 114-3, 114-4, 114-5, 114-6, as shown in FIG. 1B.

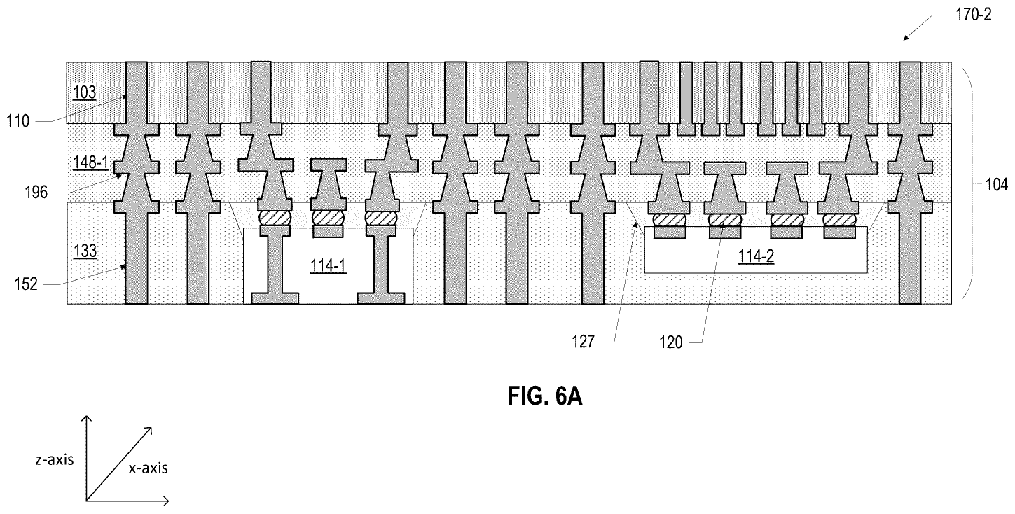

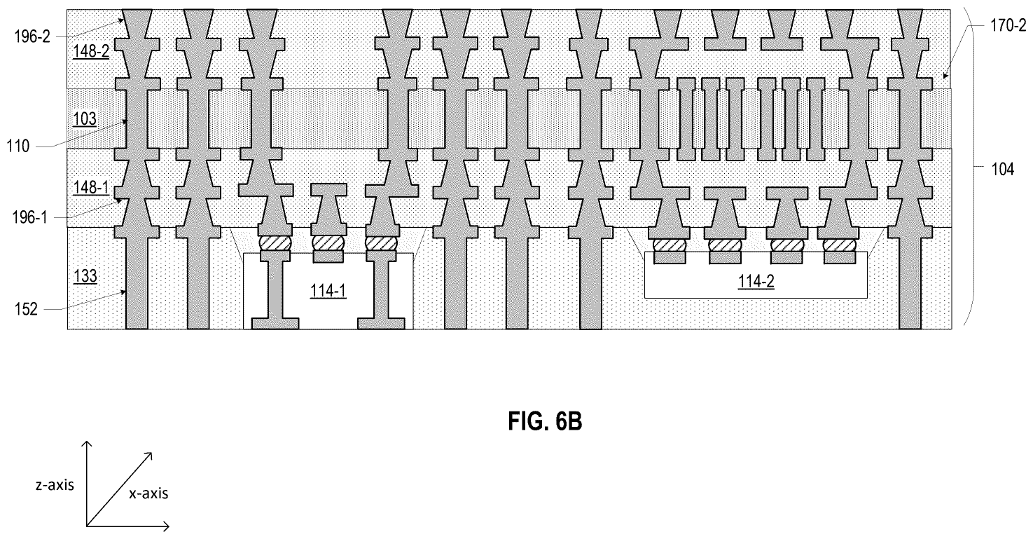

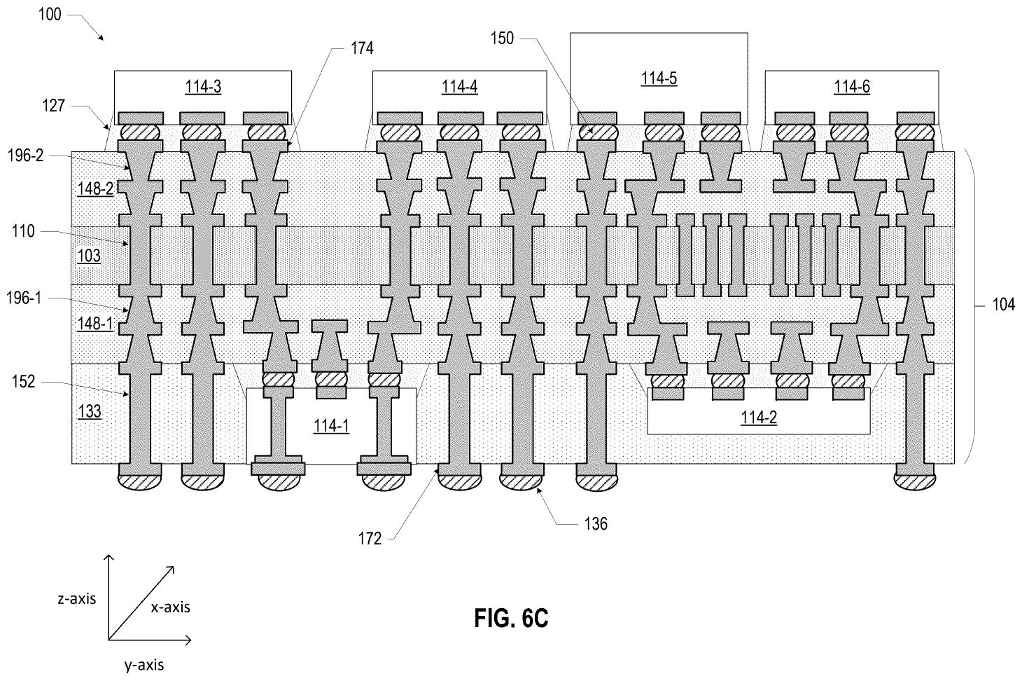

FIGS. 6A-6C are side, cross-sectional views of various stages in an example process for manufacturing the microelectronic assembly 100 similar to FIG. 1B, in accordance with various embodiments. FIG. 6A illustrates the assembly of FIG. 5F that may be manufactured using any suitable technique, including the processes described above with reference to FIGS. 5A-5F. FIG. 6A includes die 114-1, 114-2 electrically coupled by interconnects 120, as shown in FIG. 1A, instead of interconnects 106, as shown in FIG. 1B.

FIG. 6B illustrates an assembly subsequent to forming an RDL 148-2 at a second surface 170-2 (e.g., a top surface) of the core 103. The RDL 148-2 may include conductive pathways 196-2 through a dielectric material. The RDL 148-2 may be manufactured using any suitable technique, such as a PCB technique, or a redistribution layer technique.

FIG. 6C illustrates an assembly subsequent to forming conductive contacts 172, 174 on the bottom and top surfaces of the assembly of FIG. 6B, placing die 114-3, 114-4, 114-5, 114-6 on a top surface of the assembly of FIG. 6B, forming interconnects 150, and depositing an underfill material 127 around the interconnects 150. Any suitable method may be used to place die 114-3, 114-4, 114-5, 114-6, for example, automated pick-and-place. In some embodiments, the interconnects 150 may include solder. In such embodiments, the assembly of FIG. 6C may be subjected to a solder reflow process during which solder components of the interconnects 150 melt and bond to mechanically and electrically couple die 114-3, 114-4, 114-5, 114-6 to the top surface of the assembly of FIG. 6B. In some embodiments, the underfill material 127 around the interconnects 150 may be omitted. Other finishing operations may be performed on the assembly of FIG. 6C, such as depositing solder resist (not shown) and depositing solder 136 on a bottom surface. If multiple assemblies are manufactured together, the assemblies may be singulated. The assembly of FIG. 6C may itself be a microelectronic assembly 100, as shown. Further manufacturing operations may be performed on the microelectronic assembly 100 of FIG. 6C to form other microelectronic assembly 100; for example, the solder 136 may be used to couple the microelectronic assembly 100 of FIG. 6C to a package substrate 102 via interconnects 190, similar to the microelectronic assembly 100 of FIG. 1B, and/or an insulating material 133 (e.g., the second insulating material 133-2 in FIG. 1B) may be deposited on and around 114-3, 114-4, 114-5, 114-6.

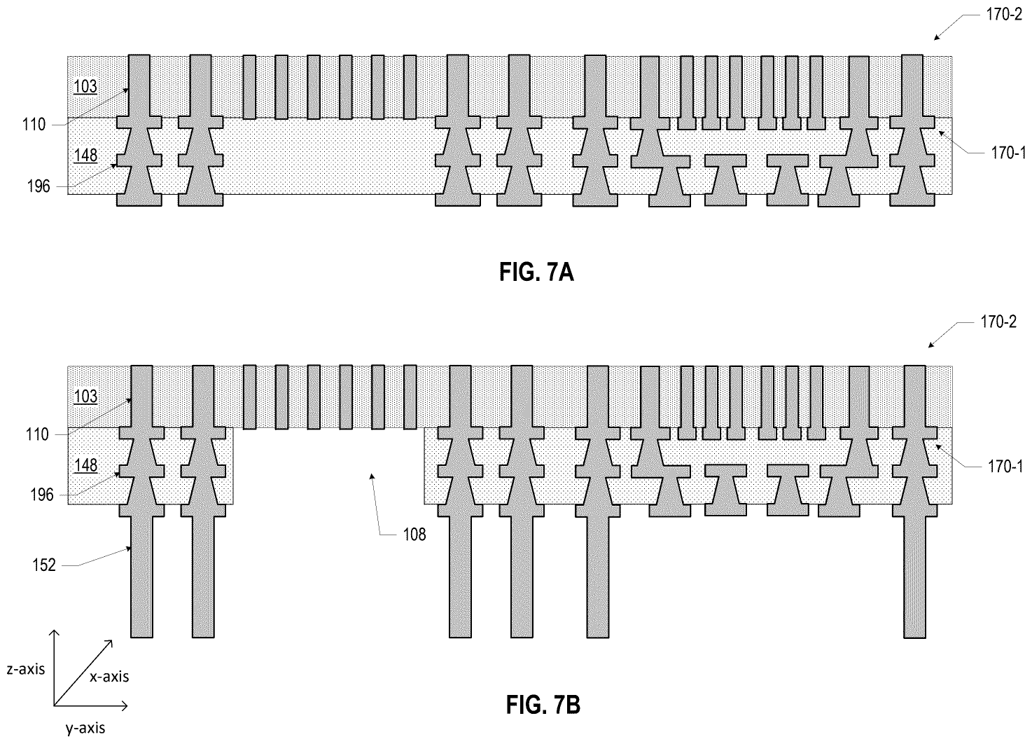

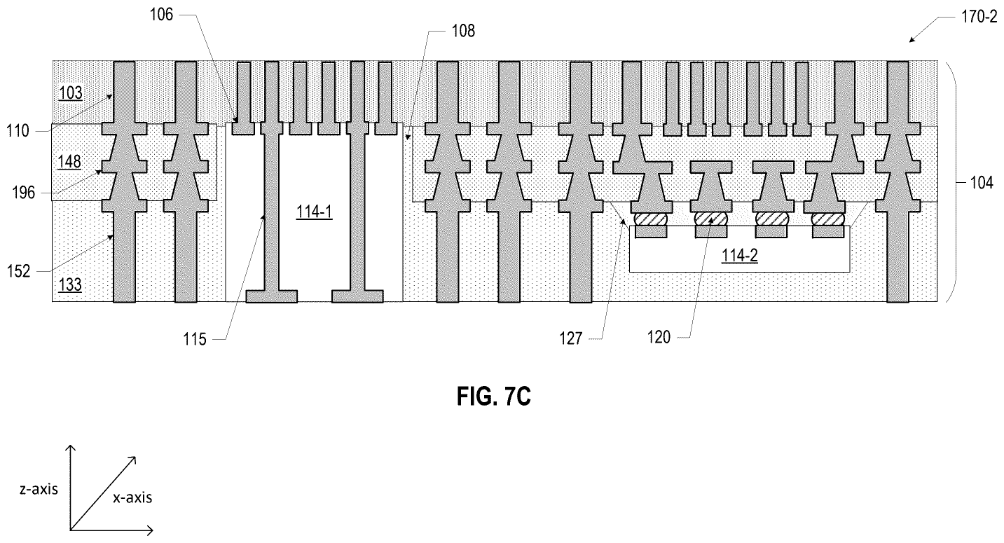

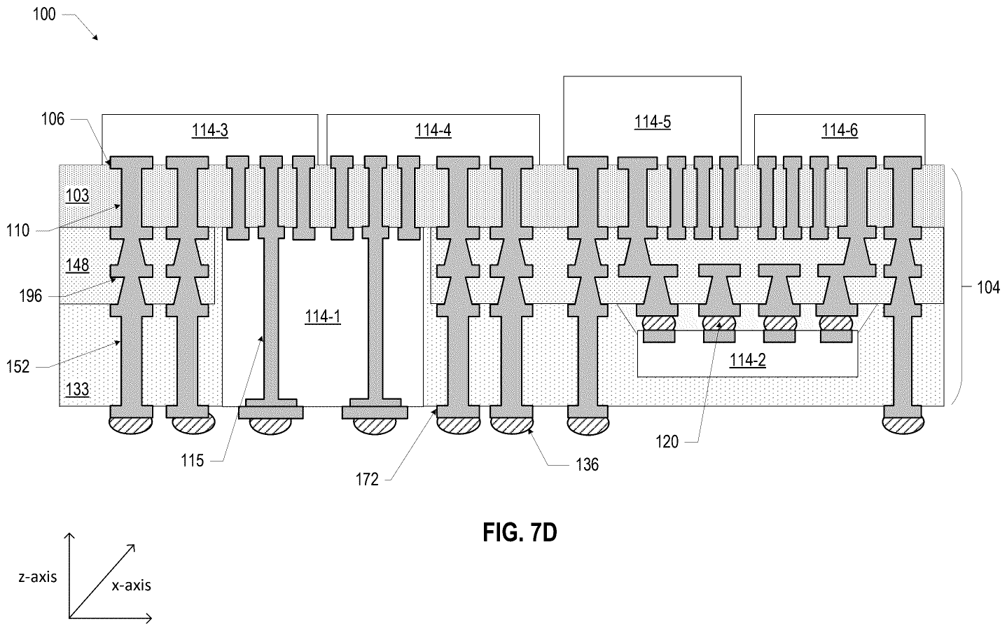

FIGS. 7A-7D are side, cross-sectional views of various stages in an example process for manufacturing the microelectronic assembly 100 of FIG. 2, in accordance with various embodiments. FIG. 7A illustrates an assembly including a core 103 having a first surface 170-1 and a second surface 170-2 and TGVs 110, and an RDL 148 having conductive pathways 196 through a dielectric material at the first surface 170-1 (e.g., a bottom surface) of the core 103. The assembly of FIG. 7A may be manufactured using any suitable techniques, including the techniques described above with reference to FIGS. 5A and 5B.

FIG. 7B illustrates an assembly subsequent to forming conductive pillars 152 on a bottom surface of the RDL 148 and to forming a cavity 108 in the dielectric material of the RDL 148. The cavity 108 may be formed using any suitable technique, including, for example, laser patterning techniques. The cavity 108 may have any suitable dimensions so that die 114-1 may be seated therein. The conductive pillars 152 may take the form of any of the embodiments disclosed herein and may be formed using any suitable process, including as described above with reference to FIG. 5C.

FIG. 7C illustrates an assembly subsequent to placing die 114-1 and forming interconnects 106, placing die 114-2 and forming interconnects 120, depositing an underfill material 127 around interconnects 120, depositing an insulating material 133 on and around die 114-1, 114-2 and conductive pillars 152, and planarizing the insulating material 133 and the conductive pillars 152, as necessary, to expose conductive contacts at the bottom surface of die 114-1. Any suitable method may be used to place die 114-1, 114-2, for example, automated pick-and-place. In some embodiments, interconnects 120 may not include solder and instead may be interconnects 106. The insulating material 133 may be any suitable material, as described above with reference to FIG. 1A, and may be formed and planarized using any suitable process, as described above with reference to FIGS. 5E and 5F.

FIG. 7D illustrates an assembly subsequent to forming conductive contacts 172 on the bottom surface of the assembly of FIG. 7C, placing die 114-3, 114-4, 114-5, 114-6 on a top surface of the assembly of FIG. 7C, and forming interconnects 106. In some embodiments, a bonding layer (e.g., bond pads in a dielectric material) may be formed on a top surface of the assembly of FIG. 7C prior to forming interconnects 106. Any suitable method may be used to place die 114-3, 114-4, 114-5, 114-6, for example, automated pick-and-place. Other finishing operations may be performed on the assembly of FIG. 7D, such as depositing solder resist (not shown) and depositing solder 136 on a bottom surface. If multiple assemblies are manufactured together, the assemblies may be singulated. The assembly of FIG. 7D may itself be a microelectronic assembly 100, as shown. Further manufacturing operations may be performed on the microelectronic assembly 100 of FIG. 7D to form other microelectronic assembly 100; for example, the solder 136 may be used to couple the microelectronic assembly 100 of FIG. 7D to a package substrate 102 via interconnects 190, similar to the microelectronic assembly 100 of FIG. 2, an insulating material 133 (e.g., the second insulating material 133-2 in FIG. 1B) may be deposited on and around 114-3, 114-4, 114-5, 114-6, and/or an RDL 148 (e.g., a second RDL 148-2, as shown in FIG. 1B) may be formed on a top surface of the core 103 prior to electrically coupling die 114-3, 114-4, 114-5, 114-6.

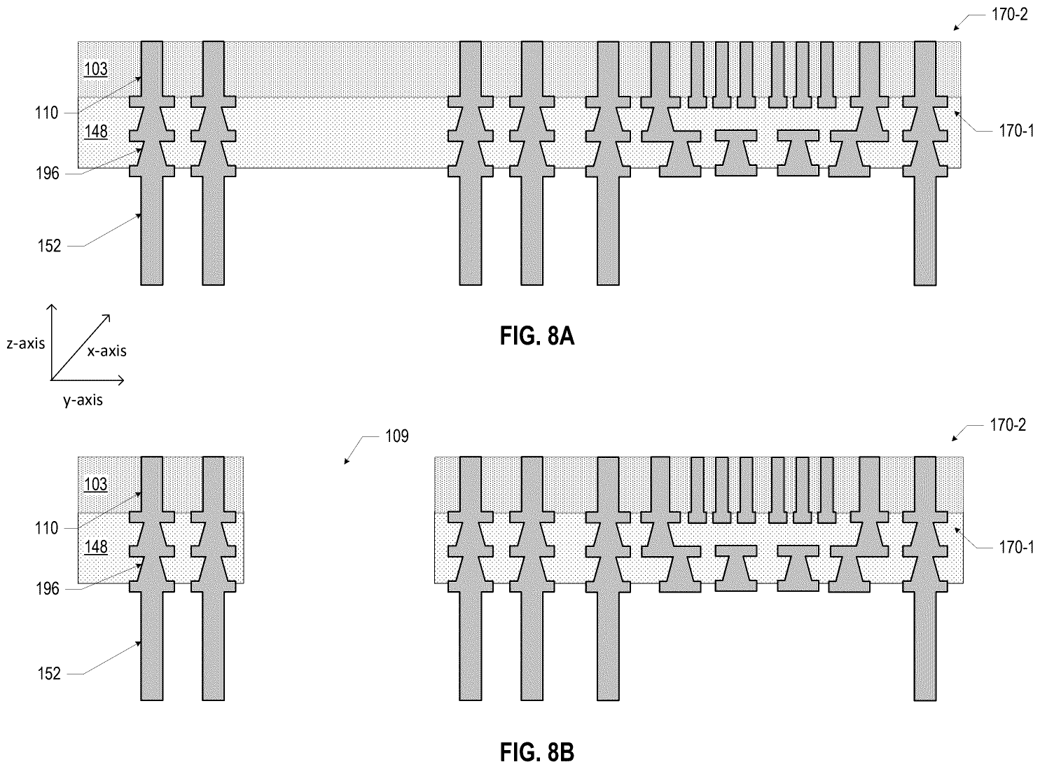

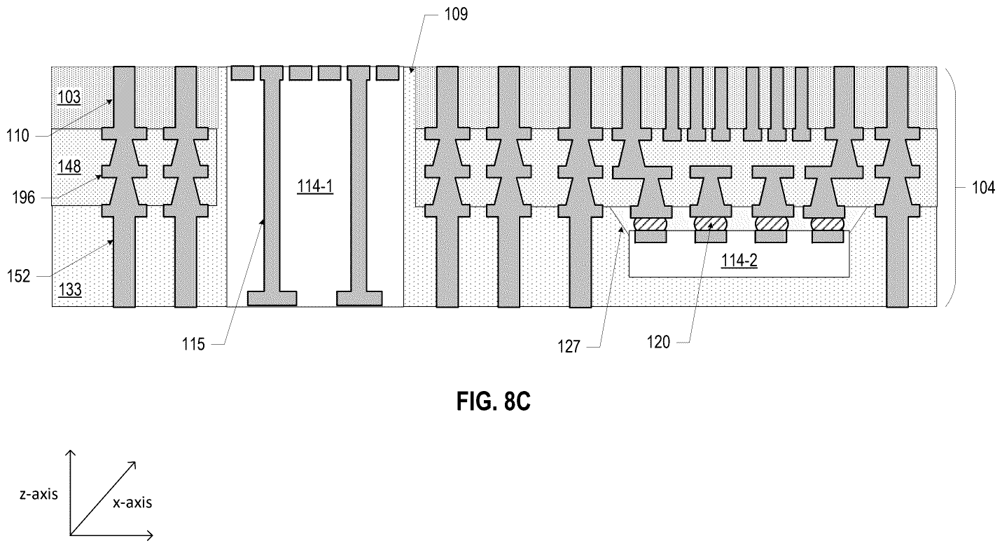

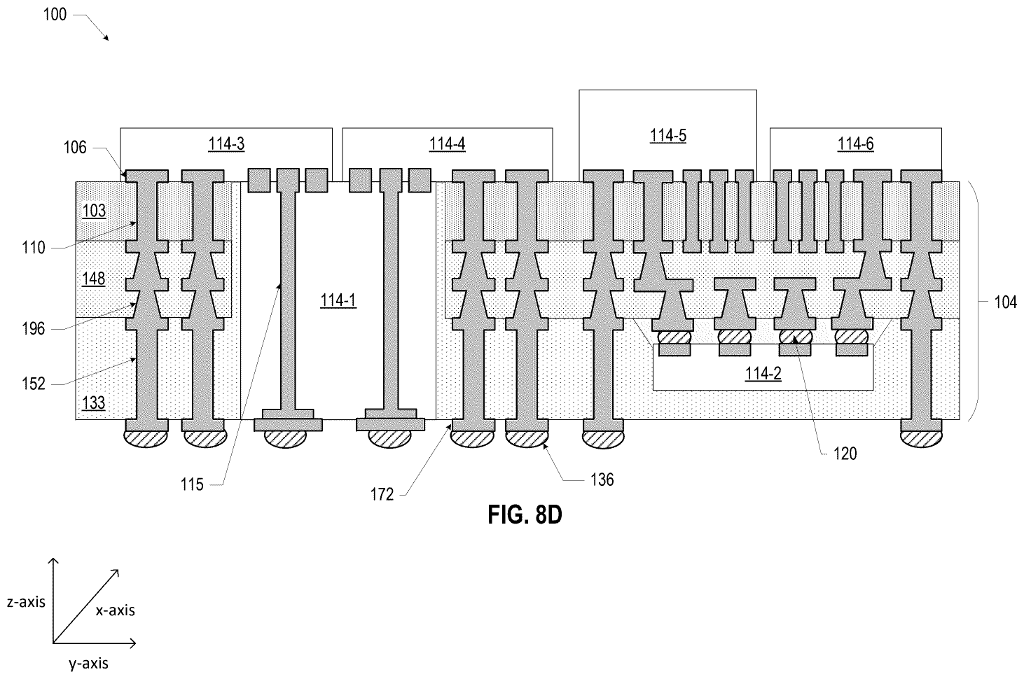

FIGS. 8A-8D are side, cross-sectional views of various stages in an example process for manufacturing the microelectronic assembly 100 of FIG. 3, in accordance with various embodiments. FIG. 8A illustrates an assembly including a core 103 having a first surface 170-1 and a second surface 170-2 and TGVs 110, an RDL 148 having conductive pathways 196 through a dielectric material at the first surface 170-1 (e.g., a bottom surface) of the core 103, and conductive pillars 152 on a bottom surface of the RDL 148. The assembly of FIG. 8A may be manufactured using any suitable techniques, including the techniques described above with reference to FIGS. 5A-5C.

FG. 8B illustrates an assembly subsequent to forming a cavity 109 in the dielectric material of the RDL 148 and in the core 103. The cavity 109 may be formed using any suitable technique, including, for example, laser patterning techniques. The cavity 109 may have any suitable dimensions so that die 114-1 may be seated therein.

FIG. 8C illustrates an assembly subsequent to placing die 114-1, placing die 114-2 and forming interconnects 120, depositing an underfill material 127 around interconnects 120, depositing an insulating material 133 on and around die 114-1, 114-2 and conductive pillars 152, and planarizing the insulating material 133 and the conductive pillars 152, as necessary, to expose conductive contacts at the bottom surface of die 114-1. Any suitable method may be used to place die 114-1, 114-2, for example, automated pick-and-place. In some embodiments, interconnects 120 may not include solder and instead may be interconnects 106. The insulating material 133 may be any suitable material, as described above with reference to FIG. 1A, and may be formed and planarized using any suitable process, as described above with reference to FIGS. 5E and 5F.

FIG. 8D illustrates an assembly subsequent to forming conductive contacts 172 on the bottom surface of the assembly of FIG. 8C, placing die 114-3, 114-4, 114-5, 114-6 on a top surface of the assembly of FIG. 8C, and forming interconnects 106. In some embodiments, a bonding layer (e.g., bond pads in a dielectric material) may be formed on a top surface of the assembly of FIG. 8C prior to forming interconnects 106. Any suitable method may be used to place die 114-3, 114-4, 114-5, 114-6, for example, automated pick-and-place. Other finishing operations may be performed on the assembly of FIG. 8D, such as depositing solder resist (not shown) and depositing solder 136 on a bottom surface. If multiple assemblies are manufactured together, the assemblies may be singulated. The assembly of FIG. 8D may itself be a microelectronic assembly 100, as shown. Further manufacturing operations may be performed on the microelectronic assembly 100 of FIG. 8D to form other microelectronic assembly 100; for example, the solder 136 may be used to couple the microelectronic assembly 100 of FIG. 8D to a package substrate 102 via interconnects 190, similar to the microelectronic assembly 100 of FIG. 3, an insulating material 133 (e.g., the second insulating material 133-2 in FIG. 1B) may be deposited on and around 114-3, 114-4, 114-5, 114-6, and/or an RDL 148 (e.g., a second RDL 148-2, as shown in FIG. 1B) may be formed on a top surface of the core 103 prior to electrically coupling die 114-3, 114-4, 114-5, 114-6.

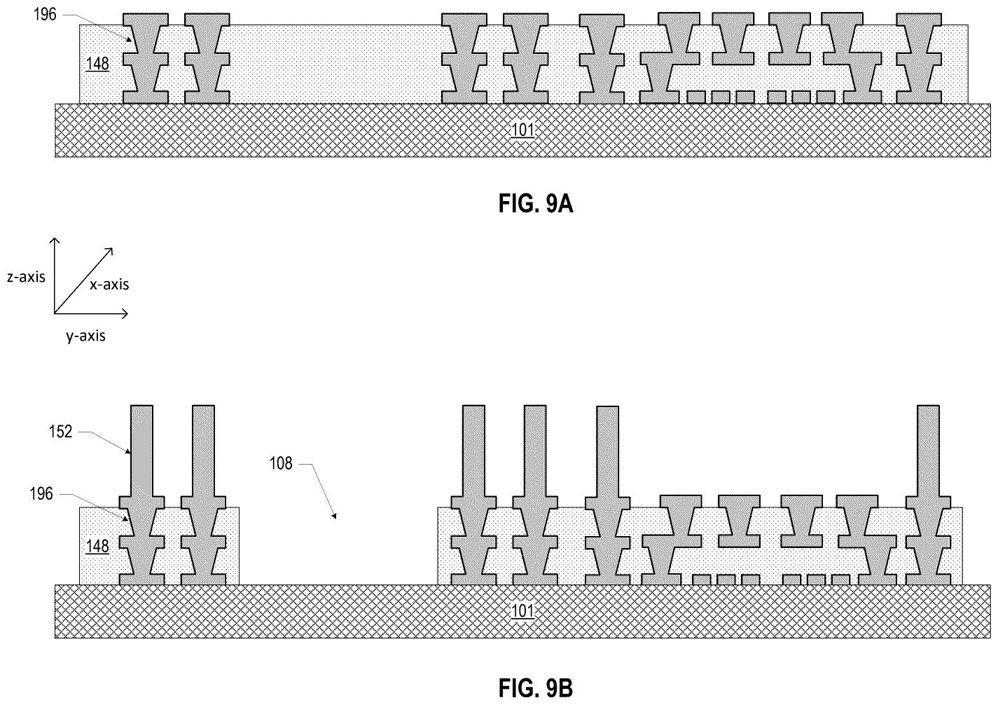

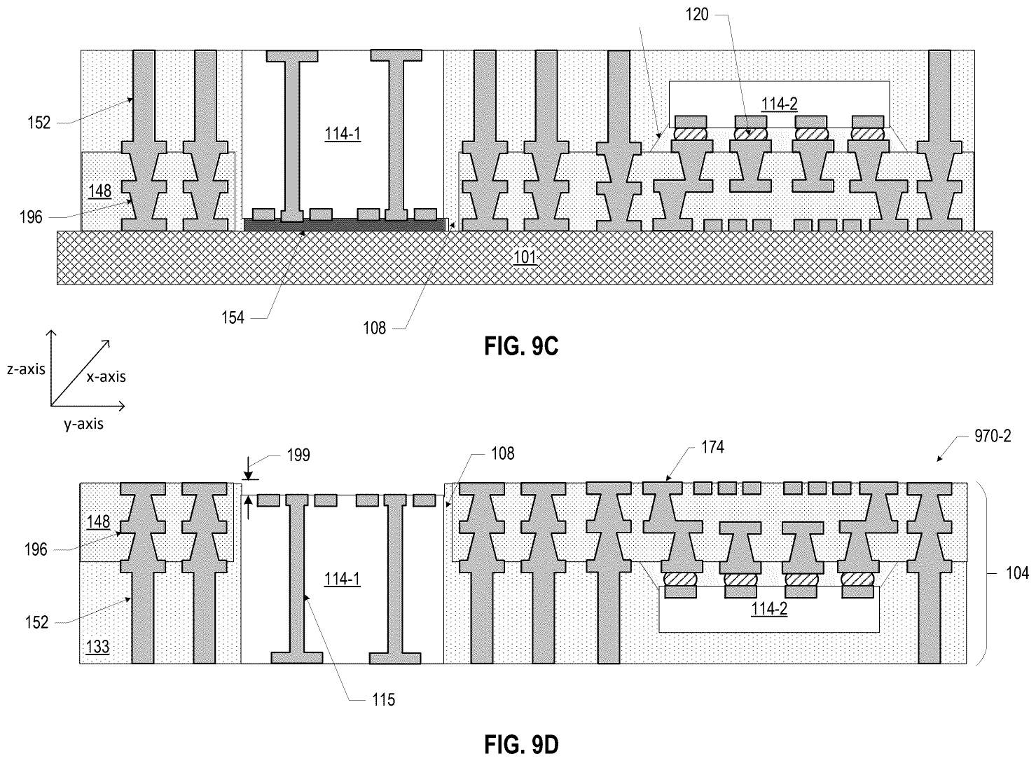

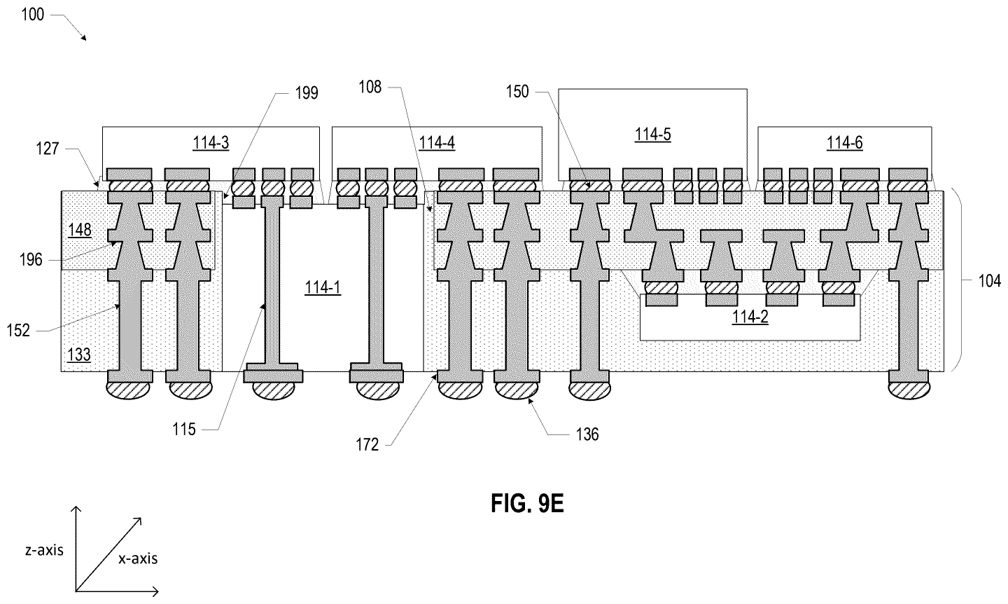

FIGS. 9A-9E are side, cross-sectional views of various stages in an example process for manufacturing the microelectronic assembly 100 of FIG. 4, in accordance with various embodiments. FIG. 9A illustrates an assembly subsequent to forming an RDL 148 having conductive pathways through a dielectric material on a carrier 101. The carrier 101 may include any suitable material for providing mechanical stability during manufacturing operations, such as glass. In some embodiments, a surface layer material (not shown), such as a solder resist material, may be deposited on the carrier prior to forming the RDL 148.

FIG. 9B illustrates an assembly subsequent to forming conductive pillars 152 on a top surface of the RDL 148 and to forming a cavity 108 in the dielectric material of the RDL 148. The cavity 108 may be formed using any suitable technique, including, for example, laser patterning techniques. The cavity 108 may have any suitable dimensions so that die 114-1 may be seated therein. The conductive pillars 152 may take the form of any of the embodiments disclosed herein and may be formed using any suitable process, including as described above with reference to FIG. 5C.

FIG. 9C illustrates an assembly subsequent to placing die 114-1, placing die 114-2 and forming interconnects 120, depositing an underfill material 127 around interconnects 120, depositing an insulating material 133 on and around die 114-1, 114-2 and conductive pillars 152, and planarizing the insulating material 133 and the conductive pillars 152, as necessary, to expose conductive contacts at the top surface of die 114-1. Die 114-1 may be attached to the carrier 101 using any suitable technique, such as die attach film (DAF) 154. Any suitable method may be used to place die 114-1, 114-2, for example, automated pick-and-place. In some embodiments, interconnects 120 may not include solder and instead may be interconnects 106. The insulating material 133 may be any suitable material, as described above with reference to FIG. 1A, and may be formed and planarized using any suitable process, as described above with reference to FIGS. 5E and 5F.

FIG. 9D illustrates an assembly subsequent to inverting the assembly of FIG. 9C and removing the carrier 101. The DAF 154 may be removed from die 114-1 such that die 114-1 may be recessed 199 from a top surface 970-2 of the assembly of FIG. 9D. The recess 199 may have a thickness (e.g., z-dimension) between 1 micron and 20 microns. As shown in FIG. 9D, conductive contacts 174 may be flush with a top surface 970-2 of the assembly of FIG. 9D.

FIG. 9E illustrates an assembly subsequent to forming conductive contacts 172 on the bottom surface of the assembly of FIG. 9D, placing die 114-3, 114-4, 114-5, 114-6 on a top surface of the assembly of FIG. 9D, forming interconnects 150, and depositing an underfill material 127 around the interconnects 150. The conductive contacts 172 may be formed using any suitable process, including a semi-additive process. Any suitable method may be used to place die 114-3, 114-4, 114-5, 114-6, for example, automated pick-and-place. In some embodiments, the interconnects 150 may include solder. In such embodiments, the assembly of FIG. 9E may be subjected to a solder reflow process during which solder components of the interconnects 150 melt and bond to mechanically and electrically couple die 114-3, 114-4, 114-5, 114-6 to the top surface of the RDL 148. In some embodiments, the underfill material 127 around the interconnects 150 may be omitted. Other finishing operations may be performed on the assembly of FIG. 9E, such as depositing solder resist (not shown) and depositing solder 136 on a bottom surface. If multiple assemblies are manufactured together, the assemblies may be singulated. The assembly of FIG. 9E may itself be a microelectronic assembly 100, as shown. Further manufacturing operations may be performed on the microelectronic assembly 100 of FIG. 9E to form other microelectronic assembly 100; for example, the solder 136 may be used to couple the microelectronic assembly 100 of FIG. 9E to a package substrate 102 via interconnects 190, similar to the microelectronic assembly 100 of FIG. 4, and/or an insulating material 133 (e.g., the second insulating material 133-2 in FIG. 1B) may be deposited on and around 114-3, 114-4, 114-5, 114-6, as shown in FIG. 1B.

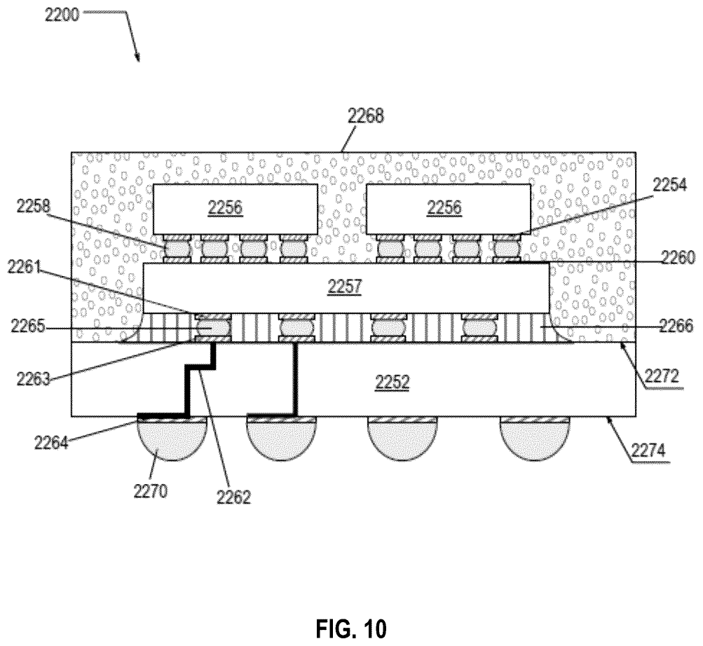

The packages disclosed herein, e.g., any of the microelectronic assemblies 100, or any further embodiments described herein, may be included in any suitable electronic component. FIGS. 10-12 illustrate various examples of packages, assemblies, and devices that may be used with or include any of the IC packages as disclosed herein.

FIG. 10 is a side, cross-sectional view of an example IC package 2200 that may include microelectronic assemblies in accordance with any of the embodiments disclosed herein. In some embodiments, the IC package 2200 may be a system-in-package (SiP).

As shown in FIG. 10, package support 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures including lines and/or vias, e.g., as discussed above with reference to FIG. 1.

Package support 2252 may include conductive contacts 2263 that are coupled to conductive pathway 2262 through package support 2252, allowing circuitry within dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, first level interconnects (FLI) 2265, and conductive contacts 2263 of package support 2252. FLI 2265 illustrated in FIG. 10 are solder bumps, but any suitable FLI 2265 may be used, such as solder bumps, solder posts, or bond wires.

IC package 2200 may include one or more dies 2256 coupled to interposer 2257 via conductive contacts 2254 of dies 2256, FLI 2258, and conductive contacts 2260 of interposer 2257. In various embodiments, interposer 2257 may include core 103 including glass as described herein. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). FLI 2258 illustrated in FIG. 10 are solder bumps, but any suitable FLI 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, underfill material 2266 may be disposed between package support 2252 and interposer 2257 around FLI 2265, and mold 2268 may be disposed around dies 2256 and interposer 2257 and in contact with package support 2252. In some embodiments, underfill material 2266 may be the same as mold 2268. Example materials that may be used for underfill material 2266 and mold 2268 are epoxies as suitable. Second level interconnects (SLI) 2270 may be coupled to conductive contacts 2264. SLI 2270 illustrated in FIG. 10 are solder balls (e.g., for a ball grid array (BGA) arrangement), but any suitable SLI 2270 may be used (e.g., pins in a pin grid array arrangement or lands in a land grid array arrangement). SLI 2270 may be used to couple IC package 2200 to another component, such as a circuit board (e.g., a motherboard), an interposer, or another IC package, as known in the art and as discussed below with reference to FIG. 12.

In embodiments in which IC package 2200 includes multiple dies 2256, IC package 2200 may be referred to as a multichip package (MCP). Dies 2256 may include circuitry to perform any desired functionality. For example, besides one or more of dies 2256 including components of dies 114 as described herein, one or more of dies 2256 may be logic dies (e.g., silicon-based dies), one or more of dies 2256 may be memory dies (e.g., high-bandwidth memory), etc. In some embodiments, at least some of dies 2256 may not include components of dies 114 as described herein.

Although IC package 2200 illustrated in FIG. 10 is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

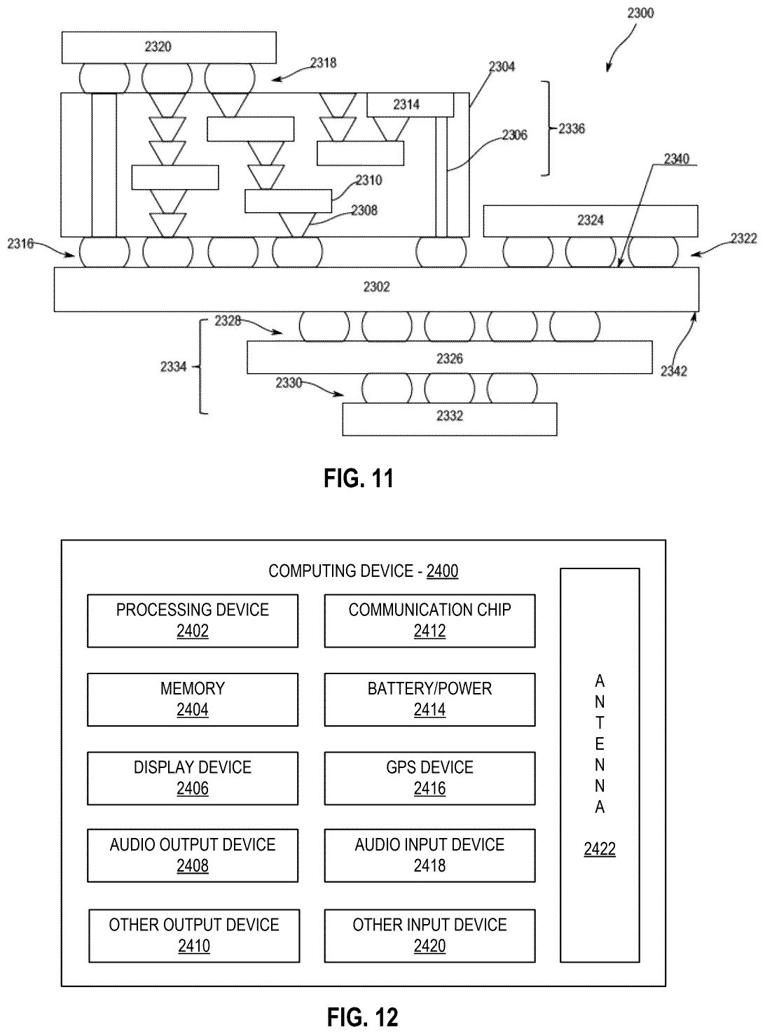

FIG. 11 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 10.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package support.

FIG. 11 illustrates that, in some embodiments, IC device assembly 2300 may include a package-on-interposer structure 2336 coupled to first face 2340 of circuit board 2302 by coupling components 2316. Although not shown so as not to clutter the drawing, package-on-interposer structure 2336 may include a core 103, such as glass layer, in some embodiments. In other embodiments, package-on-interposer structure 2336 may not include a core. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. In some embodiments, IC package 2320 may include microelectronic assembly 100, and other components as described herein, which are not shown so as not to clutter the drawing. Coupling components 2318 may take any suitable form depending on desired functionalities, such as the forms discussed above with reference to coupling components 2316. In some embodiments, IC package 2320 may be or include IC package 2200, e.g., as described above with reference to FIG. 10.

Although a single IC package 2320 is shown in FIG. 11, multiple IC packages may be coupled to interposer 2304; indeed, additional interposers may be coupled to interposer 2304. Interposer 2304 may provide an intervening package support used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in FIG. 11, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 12 is a block diagram of an example computing device 2400 that may include one or more components having one or more IC packages in accordance with any of the embodiments disclosed herein. For example, any suitable ones of the components of computing device 2400 may include microelectronic assembly 100 including glass in accordance with any of the embodiments disclosed herein. In another example, any one or more of the components of computing device 2400 may include any embodiments of IC package 2200 (e.g., as shown in FIG. 10). In yet another example, any one or more of the components of computing device 2400 may include an IC device assembly 2300 (e.g., as shown in FIG. 11).

A number of components are illustrated in FIG. 12 as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in FIG. 12, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips; note that the terms “chip,” “die,” and “IC die” are used interchangeably herein). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives of it, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

The following paragraphs provide various examples of the embodiments disclosed herein.
Example 1 is a microelectronic assembly, including a first layer, the first layer including a first material and a die surrounded by the first material; a second layer on the first layer, the second layer including a second material and a conductive pathway through the second material, wherein the conductive pathway includes a conductive trace and a conductive via, and wherein the conductive via has an inverted trapezoidal shape; and a third layer on the second layer, the third layer including a glass layer and a conductive through-glass via (TGV), wherein the conductive TGV is electrically coupled to the conductive pathway and the die is electrically coupled to the conductive TGV by the conductive pathway.
Example 2 may include the subject matter of Example 1, and may further specify that the die is electrically coupled to the conductive pathway by an interconnect, the interconnect including solder.
Example 3 may include the subject matter of Example 1 or 2, and may further specify that the die further includes a through-substrate via (TSV).
Example 4 may include the subject matter of any of Examples 1-4, and may further specify that the die is a first die, and the microelectronic assembly may further include a second die on the third layer, at a surface opposite the second layer, and electrically coupled to the conductive TGV by an interconnect.
Example 5 may include the subject matter of Example 4, and may further specify that the interconnect includes solder.
Example 6 may include the subject matter of Example 4, and may further specify that the interconnect includes a metal-metal bond and a dielectric-dielectric bond.
Example 7 may include the subject matter of any of Examples 1-6, and may further specify that the first material includes a mold material, a resin material, an epoxy material, or an underfill material, and the second material includes a build-up film, a carbon-doped dielectric, a fluorine-doped dielectric, a porous dielectric, an organic polymeric dielectric, silicon and oxygen, or silicon, oxygen, and nitrogen.
Example 8 may include the subject matter of Example 7, and may further specify that the first material includes an organic polymer with inorganic silicon oxide particles or aluminum oxide particles.
Example 9 may include the subject matter of any of Examples 1-8, and may further specify that the second layer includes a first conductive pathway through the second material, and the microelectronic assembly may further include a fourth layer on the third layer, the fourth layer including the second material and a second conductive pathway through the second material, wherein the second conductive pathway is electrically coupled to the conductive TGV.
Example 10 may include the subject matter of Example 9, and may further specify that the die in the first layer is a first die, and the microelectronic assembly may further include a second die on the fourth layer, at a surface opposite the third layer, and electrically coupled to the second conductive pathway.
Example 11 may include the subject matter of any of Examples 1-10, and may further include a conductive pillar adjacent to the die in the first material in the first layer.
Example 12 may include the subject matter of Example 11, and may further specify that a material of the conductive pillar includes one or more of copper, silver, nickel, gold, and aluminum.
Example 13 may include the subject matter of any of Examples 1-12, and may further include a package substrate electrically coupled to the first layer at a surface opposite the second layer.
Example 14 is a microelectronic assembly, including a glass layer having a first surface and an opposing second surface; a first via and a second via extending through the glass layer, the first via and the second via including a conductive material; a first material at the first surface of the glass layer, the first material including a cavity and a conductive pathway electrically coupled at the first surface to the first via in the glass layer; and a die in the cavity of the first material and electrically coupled at the first surface to the second via in the glass layer by an interconnect, wherein the die extends beyond the first material at a surface opposite the first surface of the glass layer, and wherein the die is surrounded by a second material different than the first material.
Example 15 may include the subject matter of Example 14, and may further specify that the first material includes a build-up film, a carbon-doped dielectric, a fluorine-doped dielectric, a porous dielectric, an organic polymeric dielectric, silicon and oxygen, or silicon, oxygen, and nitrogen, and the second material includes a mold material, a resin material, an epoxy material, or an underfill material.
Example 16 may include the subject matter of Example 14 or 15, and may further specify that the second material includes a mold material, a resin material, or an epoxy material.
Example 17 may include the subject matter of any of Examples 14-16, and may further specify that the die further includes a through-substrate via (TSV).
Example 18 may include the subject matter of any of Examples 14-17, and may further specify that the die is a first die, the interconnect is a first interconnect, and the microelectronic assembly may further include a second die at the second surface of the glass layer and electrically coupled to the first via and the second via in the glass layer by second interconnects.
Example 19 may include the subject matter of Example 18, and may further specify that the first interconnect or the second interconnects include solder.
Example 20 may include the subject matter of Example 18, and may further specify that the first interconnect and the second interconnects include a metal-metal bond and a dielectric-dielectric bond.
Example 21 may include the subject matter of any of Examples 14-20, and may further include a conductive pillar adjacent to the die in the second material and electrically coupled to the conductive pathway in the first material.
Example 22 may include the subject matter of Example 21, and may further specify that a material of the conductive pillar includes one or more of copper, silver, nickel, gold, and aluminum.
Example 23 may include the subject matter of Example 21, and may further specify that the die further includes a through-substrate via (TSV), and the microelectronic assembly may further include a package substrate electrically coupled to the TSV in the die and the conductive pillar in the second material.
Example 24 is a microelectronic assembly, including a first material layer including a first die having a through-substrate via (TSV) and a second die, wherein the first die and the second die are surrounded by the first material; a second material layer on the first material layer, wherein the second material includes a cavity and a conductive pathway, and wherein the first die is in the cavity; and a third die on the second material layer, wherein the third die is electrically coupled to the first die and to the conductive pathway by interconnects.
Example 25 may include the subject matter of Example 24, and may further specify that the first material includes a build-up film, a carbon-doped dielectric, a fluorine-doped dielectric, a porous dielectric, an organic polymeric dielectric, silicon and oxygen, or silicon, oxygen, and nitrogen, and the second material includes a mold material, a resin material, an epoxy material, or an underfill material.
Example 26 may include the subject matter of Example 24 or 25, and may further specify that the first material includes a mold material, a resin material, or an epoxy material.
Example 27 may include the subject matter of any of Examples 24-26, and may further specify that the interconnects include solder.
Example 28 may include the subject matter of any of Examples 24-26, and may further specify that the interconnects include a metal-metal bond and a dielectric-dielectric bond.
Example 29 may include the subject matter of any of Examples 24-28, and may further specify that a top surface of the first die is recessed as compared to a top surface of the second material layer.
Example 30 may include the subject matter of any of Examples 24-29, and may further specify that the first material layer further includes further includes a conductive pillar surrounded by the first material and electrically coupled to the conductive pathway in the second material.
Example 31 may include the subject matter of Example 30, and may further include a package substrate electrically coupled to the first die and to the conductive pillar in the first material.
Example 32 may include the subject matter of any of Examples 24-31, and may further include a glass layer between the second material layer and the third die, wherein the glass layer includes a through-glass via (TGV) electrically coupled to the conductive pathway in the second material layer and the third die is electrically coupled to the TGV, wherein the cavity in the second material layer further extends through the glass layer, and wherein the first die is in the cavity through the second material layer and the glass layer.
Example 33 may include the subject matter of Example 32, and may further specify that the first material layer further includes a conductive pillar surrounded by the first material and electrically coupled to the conductive pathway in the second material.
Example 34 may include the subject matter of Example 33, and may further specify that a material of the conductive pillar includes one or more of copper, silver, nickel, gold, and aluminum.
Example 35 may include the subject matter of Example 33, and may further include a package substrate electrically coupled to the first die and to the conductive pillar in the first material.
Example 36 may include the subject matter of any of Examples 24-35, and may further include a third material surrounding the third die.

1. A microelectronic assembly, comprising:
a first layer, the first layer including a first material and a die surrounded by the first material;
a second layer on the first layer, the second layer including a second material and a conductive pathway through the second material, wherein the conductive pathway includes a conductive trace and a conductive via, and wherein the conductive via has an inverted trapezoidal shape; and
a third layer on the second layer, the third layer including a glass layer and a conductive through-glass via (TGV), wherein the conductive TGV is electrically coupled to the conductive pathway and the die is electrically coupled to the conductive TGV by the conductive pathway.

2. The microelectronic assembly of claim 1, wherein the die is electrically coupled to the conductive pathway by an interconnect, the interconnect including solder.

3. The microelectronic assembly of claim 1, wherein the die further includes a through-substrate via (TSV).

4. The microelectronic assembly of claim 1, wherein the die is a first die, and the microelectronic assembly further comprising:
a second die on the third layer, at a surface opposite the second layer, and electrically coupled to the conductive TGV by an interconnect.

5. The microelectronic assembly of claim 1, wherein the first material includes one or more of a mold material, a resin material, an epoxy material, or an underfill material, and the second material includes a build-up film, a carbon-doped dielectric, a fluorine-doped dielectric, a porous dielectric, an organic polymeric dielectric, silicon and oxygen, or silicon, oxygen, and nitrogen.

6. The microelectronic assembly of claim 1, further comprising:
a conductive pillar adjacent to the die in the first material in the first layer.

7. The microelectronic assembly of claim 1, wherein the second layer includes a first conductive pathway through the second material, and the microelectronic assembly further comprising:
a fourth layer on the third layer, the fourth layer including the second material and a second conductive pathway through the second material, wherein the second conductive pathway is electrically coupled to the conductive TGV.

8. The microelectronic assembly of claim 7, wherein the die in the first layer is a first die, and the microelectronic assembly further comprising:
a second die on the fourth layer, at a surface opposite the third layer, and electrically coupled to the second conductive pathway.

9. A microelectronic assembly, comprising:
a glass layer having a first surface and an opposing second surface;
a first via and a second via extending through the glass layer, the first via and the second via including a conductive material;
a first material at the first surface of the glass layer, the first material including a cavity and a conductive pathway electrically coupled at the first surface to the first via in the glass layer; and
a die in the cavity of the first material and electrically coupled at the first surface to the second via in the glass layer by an interconnect, wherein the die extends beyond the first material at a surface opposite the first surface of the glass layer, and wherein the die is surrounded by a second material different than the first material.

10. The microelectronic assembly of claim 9, wherein the first material includes a build-up film, a carbon-doped dielectric, a fluorine-doped dielectric, a porous dielectric, an organic polymeric dielectric, silicon and oxygen, or silicon, oxygen, and nitrogen, and the second material includes a mold material, a resin material, an epoxy material, or an underfill material.

11. The microelectronic assembly of claim 9, wherein the die further includes a through-substrate via (TSV).

12. The microelectronic assembly of claim 9, wherein the die is a first die, the interconnect is a first interconnect, and the microelectronic assembly further comprising:
a second die at the second surface of the glass layer and electrically coupled to the first via and the second via in the glass layer by second interconnects.

13. The microelectronic assembly of claim 12, wherein the first interconnect or the second interconnects include solder.

14. The microelectronic assembly of claim 12, wherein the first interconnect and the second interconnects include a metal-metal bond and a dielectric-dielectric bond.

15. The microelectronic assembly of claim 9, wherein the die further includes a through-substrate via (TSV), and the microelectronic assembly further comprising:
a conductive pillar adjacent to the die in the second material and electrically coupled to the conductive pathway in the first material; and
a package substrate electrically coupled to the TSV in the die and the conductive pillar in the second material.

16. A microelectronic assembly, comprising:
a first material layer including a first die having a through-substrate via (TSV) and a second die, wherein the first die and the second die are surrounded by the first material;
a second material layer on the first material layer, wherein the second material includes a cavity and a conductive pathway, and wherein the first die is in the cavity; and
a third die on the second material layer, wherein the third die is electrically coupled to the first die and to the conductive pathway by interconnects.

17. The microelectronic assembly of claim 16, wherein the first material includes a build-up film, a carbon-doped dielectric, a fluorine-doped dielectric, a porous dielectric, an organic polymeric dielectric, silicon and oxygen, or silicon, oxygen, and nitrogen, and the second material includes a mold material, a resin material, an epoxy material, or an underfill material.

18. The microelectronic assembly of claim 16, wherein a top surface of the first die is recessed as compared to a top surface of the second material layer.

19. The microelectronic assembly of claim 16, further comprising:
a glass layer between the second material layer and the third die, wherein the glass layer includes a through-glass via (TGV) electrically coupled to the conductive pathway in the second material layer and the third die is electrically coupled to the TGV, wherein the cavity in the second material layer further extends through the glass layer, and wherein the first die is in the cavity through the second material layer and the glass layer.

20. The microelectronic assembly of claim 19, wherein the first material layer further includes a conductive pillar surrounded by the first material and electrically coupled to the conductive pathway in the second material.
